(19) United States
(12) Patent Application Publication
(10) Pub. No.: US 2026/0198158 A1
(43) Pub. Date: Jul. 9, 2026

(54) DISPLAY PANEL AND ELECTRONIC DEVICE INCLUDING THE SAME

(71) Applicant: Samsung Display Co., Ltd., Yongin-si (KR)

(72) Inventors: Jonghwa Park, Yongin-si (KR); Mankyu Jo, Yongin-si (KR); Kyungho Kim, Yongin-si (KR); Youngseok Seo, Yongin-si (KR)

(21) Appl. No.: 19/400,913

(22) Filed: Nov. 25, 2025

(30) Foreign Application Priority Data
Jan. 6, 2025 (KR) 10-2025-0001809

(51) Int. Cl. H10H 29/49

(52) U.S. Cl. CPC H10H 29/49

(57) ABSTRACT

One or more embodiments of the present disclosure provide a display panel including a base layer including first regions, and a second region surrounding the first regions, a pixel circuit layer above the base layer, and including pixel circuits and insulating layers in the first regions, light-emitting diodes above the pixel circuit layer, and respectively electrically connected to the pixel circuits, and a connection wiring electrically connecting adjacent ones of the pixel circuits, and including a stacked structure of a main connection wiring including a two-dimensional nanostructure, and an auxiliary connection wiring including a one-dimensional nanostructure and a zero-dimensional nanostructure.

### CROSS-REFERENCE TO RELATED APPLICATION

The present application claims priority to, and the benefit of, Korean Patent Application No. 10-2025-0001809, filed on January 6, 2025, in the Korean Intellectual Property Office, the entire disclosure of which is incorporated herein by reference.

### BACKGROUND

### 1. Field

The present disclosure relates to a display panel and an electronic device including the same.

### 2. Description of the Related Art

Generally, with development of a display panel that visually displays various electrical signals, various display panels having excellent characteristics, such as being slim, being lightweight, having low power consumption, and the like, and electronic devices including the display panels have been introduced. As an example, research and development have been actively carried out on display panels having various structures, such as flexible display panels that are foldable, rollable in a roll shape, and stretchable display panels, and electronic devices including the display panels.

### SUMMARY

Embodiments of the present disclosure provide a display panel with an improved stretchability and configured to implement high-quality images, and an electronic device including the display panel. However, such aspects are only an example, and the scope of the present disclosure is not limited thereto.

One or more embodiments of the present disclosure provide a display panel including a base layer including first regions, and a second region surrounding the first regions, a pixel circuit layer above the base layer, and including pixel circuits and insulating layers in the first regions, light-emitting diodes above the pixel circuit layer, and respectively electrically connected to the pixel circuits, and a connection wiring electrically connecting adjacent ones of the pixel circuits, and including a stacked structure of a main connection wiring including a two-dimensional nanostructure, and an auxiliary connection wiring including a one-dimensional nanostructure and a zero-dimensional nanostructure.

The two-dimensional nanostructure of the main connection wiring may include at least one of a nanoflake, a nano sheet, or a nanoplate.

The one-dimensional nanostructure of the auxiliary connection wiring may include at least one of a nanowire, a nanofiber, a nanotube, a nanorod, or a nanobelt.

The zero-dimensional nanostructure of the auxiliary connection wiring may include a nanoparticle.

The two-dimensional nanostructure, the one-dimensional nanostructure, and the zero-dimensional nanostructure may include a metal-based nanostructure.

The two-dimensional nanostructure may include an Ag nanoflake, wherein the one-dimensional nanostructure includes an Ag nanowire, and wherein the zero-dimensional nanostructure includes an Ag nanoparticle.

The auxiliary connection wiring may include a mixture of the one-dimensional nanostructure and the zero-dimensional nanostructure.

The auxiliary connection wiring may include a first auxiliary connection wiring including the one-dimensional nanostructure above the main connection wiring, and a second auxiliary connection wiring including the zero-dimensional nanostructure above the first auxiliary connection wiring.

The display panel may further include a conductive line in direct contact with the auxiliary connection wiring, and connecting the pixel circuits and the connection wiring to each other.

The auxiliary connection wiring may be above the main connection wiring, wherein the connection wiring further includes a third auxiliary connection wiring under the main connection wiring, including a different material from the main connection wiring and the auxiliary connection wiring, and including a carbon nanostructure.

The auxiliary connection wiring may be above the main connection wiring, wherein the connection wiring further includes a third auxiliary connection wiring including a two-dimensional carbon nanostructure under the main connection wiring, and a fourth auxiliary connection wiring including a one-dimensional carbon nanostructure under the third auxiliary connection wiring, and wherein the third auxiliary connection wiring and the fourth auxiliary connection wiring respectively include different materials from the main connection wiring and the auxiliary connection wiring.

An interface where the main connection wiring and the auxiliary connection wiring are in contact may be surface-processed using a polymer process or a plasma process.

The main connection wiring and the auxiliary connection wiring may further include a same elastic polymer material, wherein the base layer includes a same material as an elastic polymer material of the connection wiring.

One or more other embodiments of the present disclosure provide a display panel including a base layer including first regions, and a second region surrounding the first regions, a first pixel circuit layer above one of the first regions of the base layer, and including a transistor and insulating layers, a second pixel circuit layer above another of the first regions of the base layer, and including a transistor and insulating layers, a first light-emitting diode above the first pixel circuit layer, and electrically connected to the transistor of the first pixel circuit layer, a second light-emitting diode above the second pixel circuit layer, and electrically connected to the transistor of the second pixel circuit layer, and a connection wiring electrically connecting the transistor of the first pixel circuit layer to the transistor of the second pixel circuit layer, and including a main connection wiring and an auxiliary connection wiring including respective nanostructures of different dimensions.

The main connection wiring may include a two-dimensional nanostructure including at least one of a nanoflake, a nano sheet, or a nanoplate.

The auxiliary connection wiring may include at least one of a one-dimensional nanostructure including at least one of a nanowire, a nanofiber, a nanotube, a nanorod, or a nanobelt, or a zero-dimensional nanostructure including a nanoparticle.

The main connection wiring and the auxiliary connection wiring may include a same metal, and may include different nanostructure materials from each other.

One or more other embodiments of the present disclosure provide an electronic device including a display panel, the display panel including a base layer including first regions, and a second region surrounding the first regions, a pixel circuit layer above the base layer, and including pixel circuits and insulating layers in the first regions, light-emitting diodes above the pixel circuit layer, and respectively electrically connected to the pixel circuits, and a connection wiring electrically connecting adjacent ones of the pixel circuits, and including a stacked structure of a main connection wiring including a two-dimensional nanostructure, and an auxiliary connection wiring including a one-dimensional nanostructure and a zero-dimensional nanostructure.

The two-dimensional nanostructure may include at least one of a nanoflake, a nano sheet, or a nanoplate, wherein the one-dimensional nanostructure includes at least one of a nanowire, a nanofiber, a nanotube, a nanorod, or a nanobelt, and wherein the zero-dimensional nanostructure includes a nanoparticle.

The two-dimensional nanostructure of the main connection wiring and the one-dimensional nanostructure or the zero-dimensional nanostructure of the auxiliary connection wiring may include a same metal.

According to some embodiments of the present disclosure, a display panel with improved stretchability and capable of implementing images of suitable quality, and an electronic device including the display panel, may be provided. The above aspects are only examples, and the present disclosure is not limited thereto.

### BRIEF DESCRIPTION OF THE DRAWINGS

FIG. 1 is a schematic perspective view of a display panel according to one or more embodiments of the present disclosure.

FIGS. 2A and 2B are perspective views of the display panel of FIG. 1 in a state stretched in a first direction.

FIG. 2C is a perspective view of the display panel of FIG. 1 in a state stretched in a second direction.

FIG. 2D is a perspective view of the display panel of FIG. 1 in a state stretched in the first direction and the second direction.

FIG. 2E is a perspective view of the display panel of FIG. 1 in a state stretched in a third direction.

FIG. 3 is a schematic plan view of a display panel according to one or more embodiments of the present disclosure.

FIG. 4 is a schematic plan view of the arrangement of pixels of a display panel according to one or more embodiments of the present disclosure.

FIG. 5 is a schematic cross-sectional view of a display panel according to one or more embodiments of the present disclosure.

FIGS. 6A to 6C are equivalent circuit diagrams of a pixel of a display panel according to one or more embodiments of the present disclosure.

FIGS. 7A and 7B are schematic cross-sectional views of a light-emitting diode of a display panel according to one or more embodiments of the present disclosure.

FIG. 8 is a schematic plan view of a display panel according to one or more embodiments of the present disclosure.

FIG. 9 is a schematic cross-sectional view of a portion of a display panel according to one or more embodiments of the present disclosure.

FIG. 10 is an excerpted perspective view of a connection wiring of a display panel according to one or more embodiments of the present disclosure.

FIGS. 11A and 11B are schematic cross-sectional views of a connection wiring of a display panel according to one or more embodiments of the present disclosure.

FIG. 12 is an excerpted perspective view of a connection wiring of a display panel according to one or more other embodiments of the present disclosure.

FIG. 13 is a schematic cross-sectional view of a connection wiring of a display panel according to one or more other embodiments of the present disclosure.

FIGS. 14A and 14B are excerpted cross-sectional views of a connection wiring of a display panel according to one or more other embodiments of the present disclosure.

FIG. 15 is an excerpted perspective view of a connection wiring of a display panel according to one or more other embodiments of the present disclosure.

FIG. 16A is a schematic perspective view of an electronic device including a display panel according to one or more embodiments of the present disclosure.

FIG. 16B is a block diagram of an electronic device including a display panel according to one or more embodiments of the present disclosure.

FIGS. 17A to 17I are schematic perspective views of an electronic device including a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross- hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

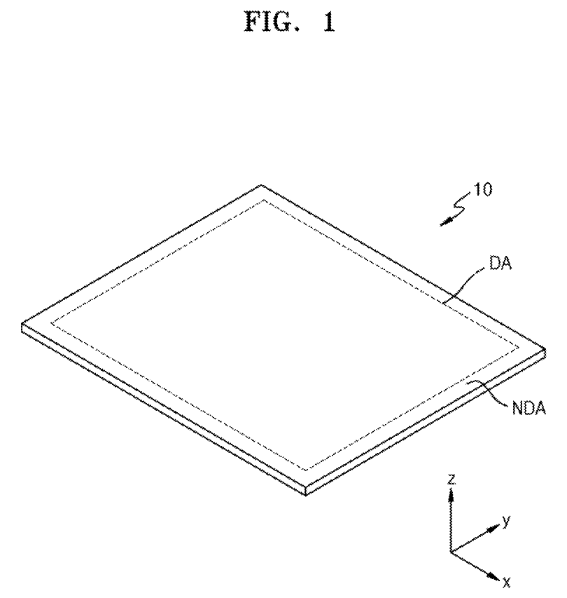

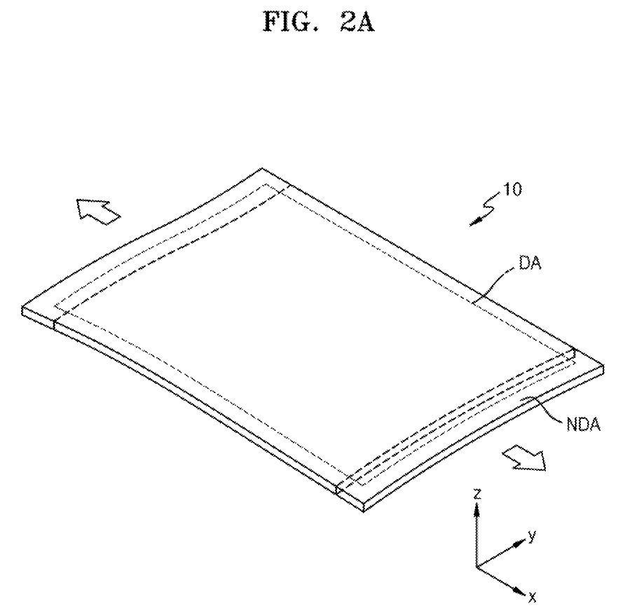

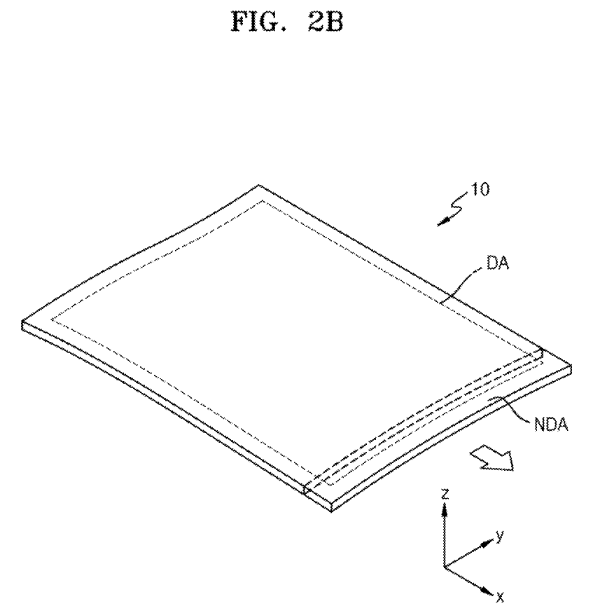

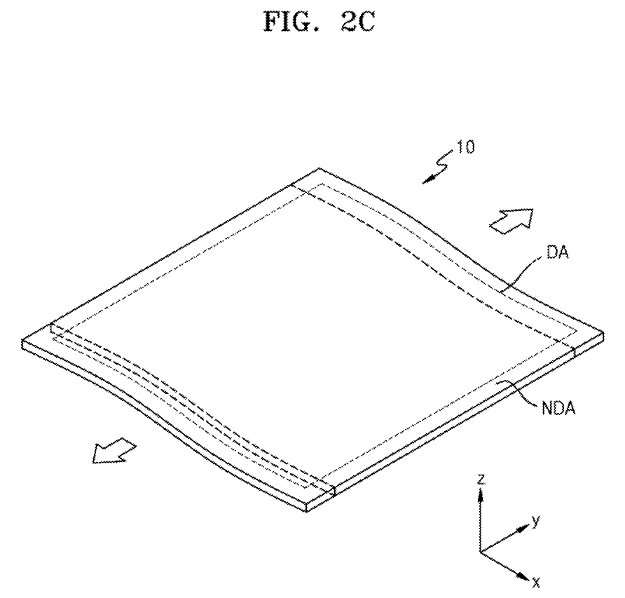

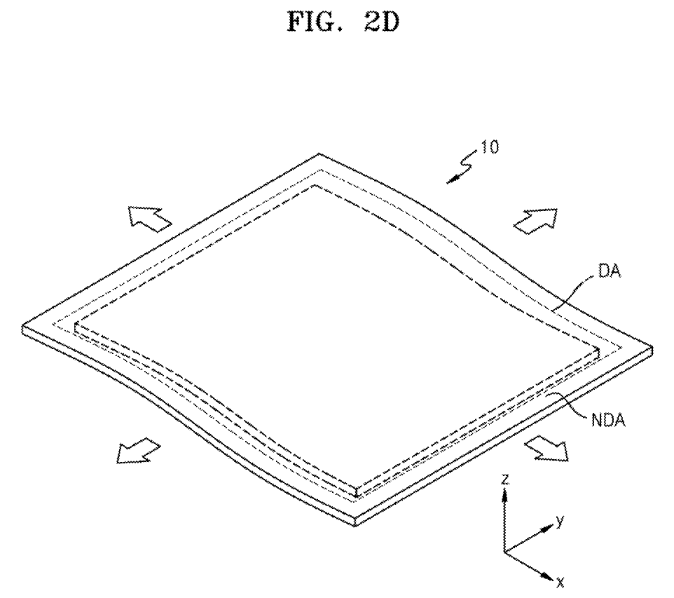

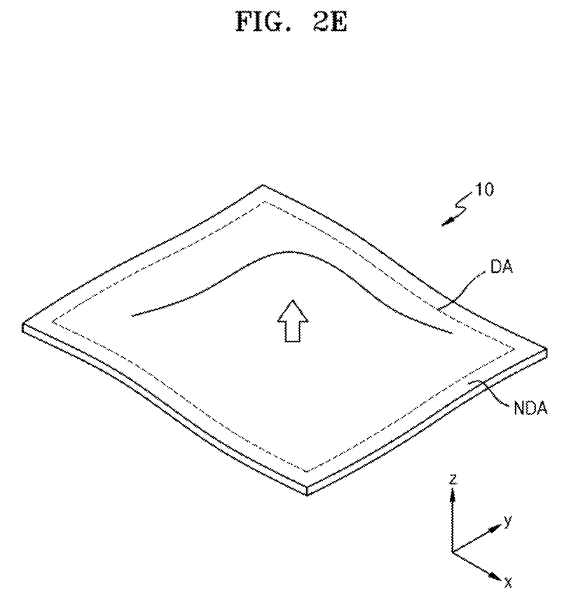

FIG. 1 is a schematic perspective view of a display panel 1 according to one or more embodiments of the present disclosure. FIGS. 2A and 2B are perspective views of the display panel 1 of FIG. 1 in a state stretched in a first direction. FIG. 2C is a perspective view of the display panel 1 of FIG. 1 in a state stretched in a second direction. FIG. 2D is a perspective view of the display panel 1 of FIG. 1 in a state stretched in the first direction and the second direction. FIG. 2E is a perspective view of the display panel 1 of FIG. 1 in a state stretched in a third direction.

Referring to FIG. 1, the display panel 1 may include a display area DA and a non-display area NDA. The display area DA may include a plurality of pixels. The display panel 1 may be configured to display images by using light emitted from the plurality of pixels. The non-display area NDA may be located outside the display area DA. The non-display area NDA may entirely surround the display area DA (e.g., in plan view).

The display panel 1 may be stretched or shrunk in various directions. The display panel 1 may be stretched in the first direction (e.g., an x direction and/or -x direction) by an external force exerted by an external object or a user. In one or more embodiments, as shown in FIGS. 2A and 2B, the display area DA and/or the non-display area NDA of the display panel 1 may be stretched in the first direction (e.g., the x direction and/or -x direction). As an example, as shown in FIG. 2A, the display area DA and/or the non-display area NDA may be stretched in the x direction and -x direction, or as shown in FIG. 2B, be stretched in the x direction with one side of the display panel 1 fixed.

The display panel 1 may be stretched in the second direction (e.g., a y direction and/or -y direction) by an external force exerted by an external object or a user. In one or more embodiments, as shown in FIG. 2C, the display area DA and/or the non-display area NDA of the display panel 1 may be stretched in the y direction and -y direction. In one or more other embodiments, the display panel 1 may be stretched in the y direction or -y direction with one side of the display panel 1 fixed.

The display panel 1 may be stretched in a plurality of directions, for example, the first direction (e.g., the x direction and/or -x direction) and the second direction (e.g., the y direction and/or -y direction) by an external force exerted by an external object or a portion of a person’s body. As shown in FIG. 2D, the display area DA and/or the non-display area NDA of the display panel 1 may be stretched in the ±x directions and ±y directions.

The display panel 1 may be stretched in a third direction (e.g., a z direction and/or -z direction) by an external force exerted by an external object or a portion of a person's body. In one or more embodiments, FIG. 2E shows a portion of the display panel 1, for example, a partial region of the display area DA protrudes in the z direction. In one or more other embodiments, a portion of the display panel 1, for example, a partial region of the display area DA, may protrude in the z direction (or may be recessed in the -z direction).

Although it is shown in FIGS. 2A to 2E that the display panel 1 is stretched in the first direction, the second direction, and/or the third direction, the present disclosure is not limited thereto. In one or more other embodiments, the display panel 1 may be variously deformed into an irregular shape by, for example, bending or twisting around two or more axes.

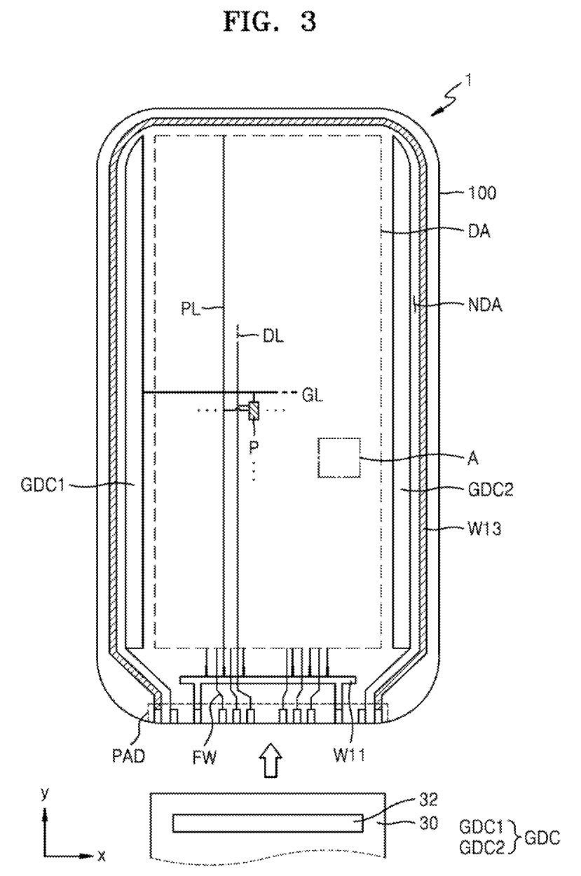

FIG. 3 is a schematic plan view of the display panel 1 according to one or more embodiments of the present disclosure.

Referring to FIG. 3, the display panel 1 may include the display area DA, and the non-display area NDA surrounding the display area DA (e.g., surrounding in plan view). Pixels P are located in the display area DA of a substrate 100. The pixels P may each be configured to display images by using light emitted from a light-emitting element, such as a light-emitting diode. Each light-emitting diode may be configured to emit, for example, red, green, or blue light.

Each light-emitting diode may be electrically connected to a pixel circuit, and each pixel circuit may include transistors and a storage capacitor. The pixel circuits may each be electrically connected to peripheral circuits and peripheral wirings located in the non-display area NDA. The peripheral circuits located in the non-display area NDA may include a gate driver (e.g., gate-driving circuit) GDC and a terminal section PAD. The peripheral wirings may include a driving voltage supply wiring W11, a common voltage supply wiring W13, and a fan-out wiring FW.

The gate driver GDC may include drivers for providing electrical signals to a gate electrode of each of the transistors electrically connected to the light-emitting elements. For example, the gate driver GDC may be configured to apply scan signals to each of the pixel circuits through a gate line GL, the pixel circuits corresponding to the pixels P.

The gate driver GDC may include a first gate driver GDC1 and a second gate driver GDC2 located on two opposite sides with the display area DA therebetween. The second gate driver GDC2 may be located on the opposite side of the first gate driver GDC1 with respect to the display area DA, and may be approximately parallel to the first gate driver GDC1. Some of the pixel circuits may be electrically connected to the first gate driver GDC1, and the others may be electrically connected to the second gate driver GDC2. In one or more embodiments, the second gate driver GDC2 may be omitted.

The terminal section PAD may be located on one side of the substrate 100. The terminal section PAD may be exposed and connected to a display circuit board 30 by not being covered by an insulating layer. A display driver 32 may be located on the display circuit board 30 (as used herein, “located on” may mean “above”). The display driver 32 may be configured to generate control signals transferred to the first gate driver GDC1 and the second gate driver GDC2. The display driver 32 may be configured to generate data signals, and the generated data signals may be transferred to the pixel circuits through the fan-out wiring FW, and through data lines DL connected to the fan-out wiring FW.

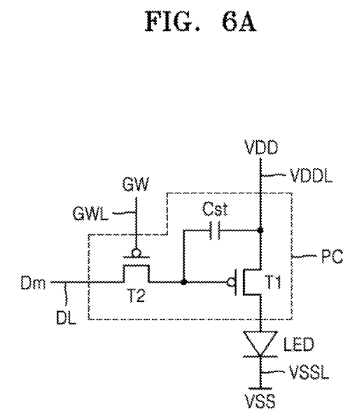

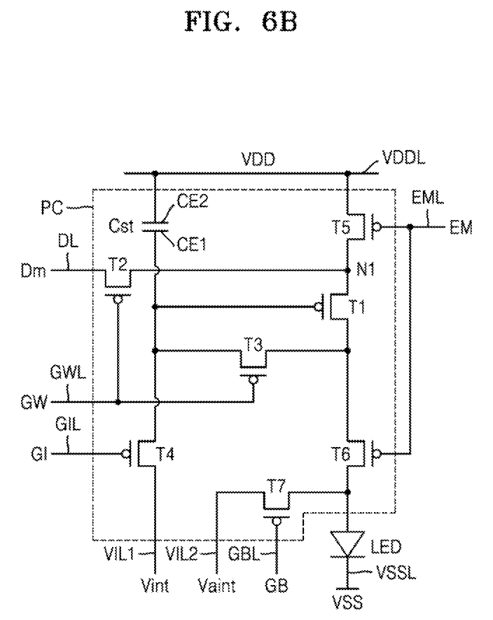

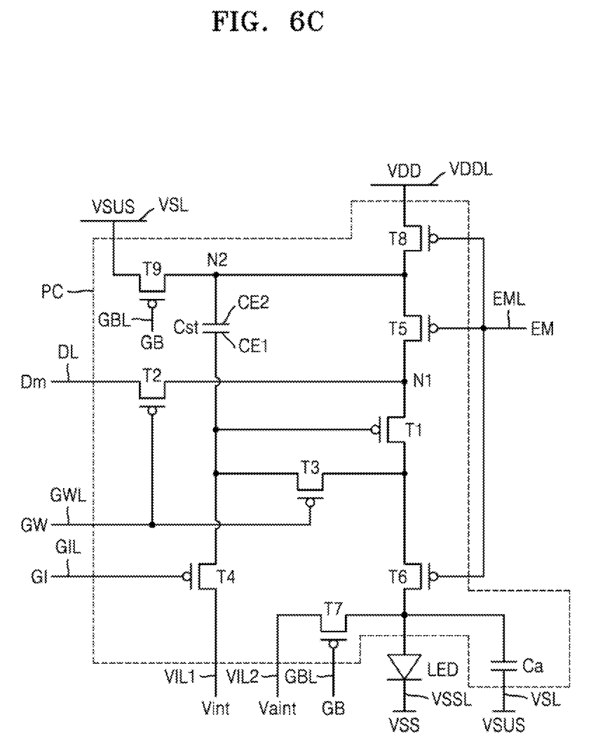

The display driver 32 may supply a first power voltage VDD (FIG. 6A) to the driving voltage supply wiring W11, and may supply a second power voltage VSS (FIG. 6A) to the common voltage supply wiring W13. The first power voltage VDD (FIG. 6A) may be applied to the pixel circuit of the pixel P through a driving voltage line PL connected to the driving voltage supply wiring W11, and the second power voltage VSS (FIG. 6A) may be connected to the common voltage supply wiring W13 and applied to an opposite electrode of a light-emitting element. The driving voltage supply wiring W11 may extend in the x direction below the display area DA. The common voltage supply wiring W13 may have a loop shape having one open side to partially surround the display area DA.

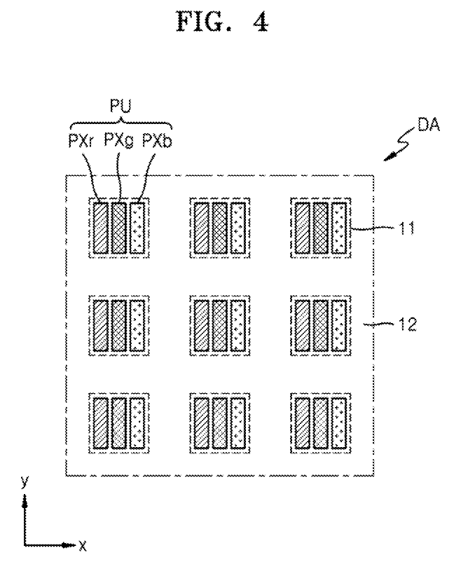

FIG. 4 is a schematic plan view of the arrangement of the pixels of the display panel according to one or more embodiments of the present disclosure.

Referring to FIG. 4, the display area DA may include first regions 11, and a second region 12 surrounding each of the first regions 11. The first regions 11 may be repeatedly arranged in the first direction (e.g., the x direction) and the second direction (e.g., the y direction).

The display area DA may include the first region 11 and the second region 12 having different elongations. As an example, the display panel 1 may include the first region 11 with a relatively low elongation, and the second region 12 with a relatively high elongation. In the present specification, an elongation is a numerical value representing a change ΔL/L in length by which the display panel 1 may be stretched without a physical damage to the display panel 1 when external force is applied to the display panel 1. Here, ΔL is the amount of change in length of the display panel 1, and L represents an initial length of the display panel 1. Accordingly, elongations of the first region 11 and the second region 12 may respectively represent changes in length of the first region 11 and the second region 12 when the same external force is applied to the first region 11 and the second region 12.

When an elongation of the first region 11 is less than an elongation of the second region 12, it may represent that deformation of the first region 11 occurs relatively little due to an external force. Accordingly, the first region 11 may be referred to as a low deformation region, and the second region 12 may be referred to as a high deformation region.

The first regions 11 may be apart from each other and arranged two-dimensionally in the display area DA. The first regions 11 may be regions in which pixels are located, and may be referred to as a pixel area or an emission area. One or more pixels may be located in each of the first regions 11. A pixel unit PU provided as a set of the pixels may be provided in the first region 11, and each pixel unit PU may include a red pixel PXr, a green pixel PXg, and a blue pixel PXb.

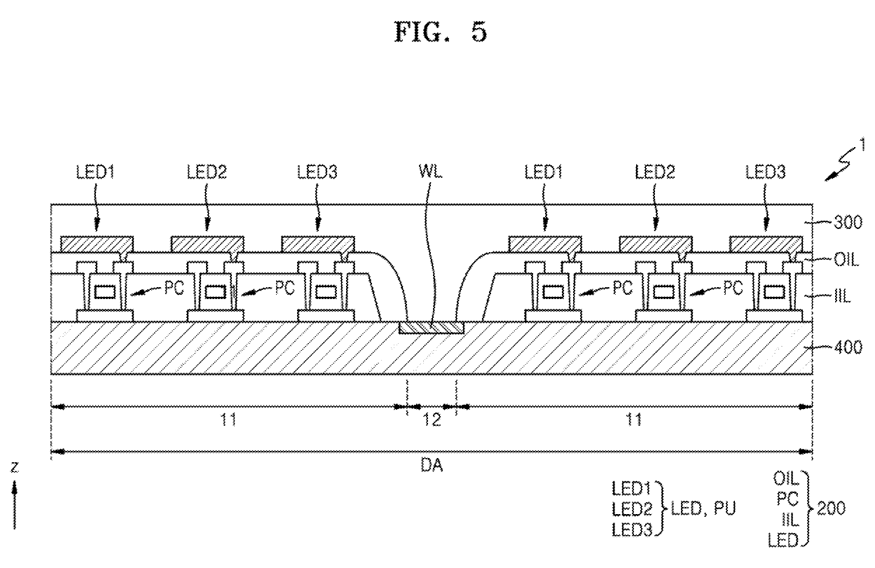

The second region 12 may be located between adjacent first regions 11. As shown in FIG. 4, in a plan view, the second region 12 may have a shape surrounding each of the first regions 11. The second region 12 may be a region across which a connection wiring for electrically connecting pixel circuits PC (FIG. 5) respectively located in adjacent two first regions 11 passes.

FIG. 5 is a schematic cross-sectional view of the display panel according to one or more embodiments of the present disclosure.

Referring to FIG. 5, the display area DA may include the first region 11 and the second region 12, and the second region 12 may connect the first regions 11 located adjacent to each other. The first region 11 is a region having a relatively lower elongation than the second region 12 and may include a light-emitting diode LED and the pixel circuit PC. The second region 12 is a region having a relatively higher elongation than the first region 11, and may include a connection wiring WL included in a signal line supplying signals to each of the pixel circuits PC.

The first region 11 and the second region 12 may be formed in a base layer 400. In other words, each of the first region 11 and the second region 12 may be defined in the base layer 400. The light-emitting element LED and the pixel circuit PC may be located in the first region 11 of the base layer 400, and the connection wiring WL may be located in the second region 12 of the base layer 400.

The base layer 400 may absorb stress that may occur while the display panel 1 is stretched. The base layer 400 may include an elastic polymer (or an elastic polymer material). As an example, the base layer 400 may include at least one of thermoplastic polyurethane, polyester, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or Ecoflex™ (Ecoflex™ being a registered trademark of Smooth-On, Inc., Macungie, PA).

A display layer 200 may be located in the first region 11 of the base layer 400. The display layer 200 may include an inorganic insulating layer IIL, the pixel circuit PC, an organic insulating layer OIL, and the light-emitting diode LED. The pixel circuit PC may be located on the base layer 400, and the inorganic insulating layer IIL may be located between electrodes included in the pixel circuit PC. The organic insulating layer OIL may be located on the inorganic insulating layer IIL to cover the pixel circuit PC. The light-emitting diode LED may be located on the organic insulating layer OIL, and may be electrically connected to the pixel circuit PC corresponding thereto. The inorganic insulating layer IIL may include an inorganic insulating material, such as silicon nitride and/or silicon oxide, and the organic insulating layer OIL may include an organic insulating material, such as polyimide.

In one or more embodiments, one pixel circuit PU may be located in one first region 11. As described above, the pixel unit PU may include the red pixel PXr (FIG. 4), the green pixel PXg (FIG. 4), and the blue pixel PXb (FIG. 4). The red pixel PXr (FIG. 4) may include a first light-emitting diode LED1, the green pixel PXg (FIG. 4) may include a second light-emitting diode LED2, and the blue pixel PXb (FIG. 4) may include a third light-emitting diode LED3. As an example, the first light-emitting diode LED1 may emit red light, the second light-emitting diode LED2 may emit green light, and the third light-emitting diode LED3 may emit blue light. In one or more embodiments, the light-emitting diode LED may also emit white light.

The connection wiring WL may be located in the second region 12 of the base layer 400. In one or more embodiments, as shown in FIG. 5, the connection wiring WL may be located on the base layer 400 and located relatively lower than the display layer 200. In other words, the base layer 400 may be located to cover the connection wiring WL located on the backside of the display layer 200. Accordingly, the thickness of the base layer 400 corresponding to the second region 12 may be less than the thickness of the base layer 400 corresponding to the first region 11. However, the connection wiring WL is not limited thereto and the connection wiring WL may be located on the base layer 400 and located on substantially the same layer as a partial layer of the display layer 200.

The connection wiring WL may include a material having both high stretchability and high electrical characteristics. In one or more embodiments, the connection wirings located in the second region 12 may include liquid metal. In one or more other embodiments, the connection wirings may include a metal nanostructure and an elastic polymer. In one or more other embodiments, the connection wirings may include a conductive composite material including elastomer.

In one or more embodiments, a protective layer 300 may be located on the light-emitting diode LED. The protective layer 300 may be located in both the first region 11 and the second region 12. That is, the protective layer 300 may be located to cover the display area DA entirely. The protective layer 300 may cover the light-emitting diode LED and the connection wiring WL. The protective layer 300 may absorb stress that may occur while the display panel 10 is stretched. For example, the protective layer 300 may reduce or prevent the transfer of stress to the light-emitting diode LED and the pixel circuit PC, wherein the stress may occur while the display panel 10 is stretched.

The protective layer 300 may include an elastic polymer. The protective layer 300 may include at least one of thermoplastic polyurethane, polyester, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, or polydimethylsiloxane (PDMS). In one or more embodiments, the protective layer 300 may include the same material as the base layer 400. However, the protective layer 300 is not limited thereto and may include a different material from the base layer 400.

FIGS. 6A to 6C are equivalent circuit diagrams of a pixel of the display panel according to one or more embodiments of the present disclosure.

Referring to FIG. 6A, a light-emitting diode LED corresponding to a pixel may be electrically connected to the pixel circuit PC, and the pixel circuit PC may include a first transistor T1, a second transistor T2, and a storage capacitor Cst. The pixel circuit PC may be electrically connected to a signal line and a voltage line. The signal line may include a gate line GL (FIG. 3), such as a scan signal line GWL, and a data line DL, and the voltage line may include a first voltage line VDDL. In this case, the first voltage line VDDL may be connected to the driving voltage supply wiring W11 (FIG. 3), and a second voltage line VSSL may be connected to the common voltage supply wiring W13 (FIG. 3).

The second transistor T2 may be electrically connected to the scan signal line GWL and the data line DL. The scan signal line GWL may provide a scan signal GW to a gate electrode of the second transistor T2. The second transistor T2 is configured to transfer a data signal Dm to the first transistor T1 according to a scan signal GW input from the scan signal line GWL, wherein the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor, and may control a driving current flowing through the light-emitting diode LED. The first transistor T1 may be connected to the first voltage line VDDL and the storage capacitor Cst. The first transistor T1 may control the driving current flowing from the first voltage line VDDL to the light-emitting diode LED in response to a voltage value stored in the storage capacitor Cst. The light-emitting diode LED may be configured to emit light having a brightness (e.g., preset brightness) corresponding to the driving current. A first electrode of the light-emitting diode LED may be electrically connected to the first transistor T1, and a second electrode may be electrically connected to the second voltage line VSSL supplying the second power voltage VSS.

Although it is shown in FIG. 6A that the pixel circuit PC includes two transistors and one storage capacitor, the pixel circuit PC may include three or more transistors in one or more other embodiments.

Referring to FIG. 6B, the pixel circuit PC may include the first transistor T1, the second transistor T2, a third transistor T3, a fourth transistor T4, a fifth transistor T5, a sixth transistor T6, a seventh transistor T7, and the storage capacitor Cst.

The pixel circuit PC is electrically connected to signal lines and voltage lines. The signal lines may include the gate line GL (FIG. 3), such as the scan signal line GWL, a bypass control line GBL, an initialization control line GIL, and an emission control line EML, and the data line DL. The voltage lines may include first and second initialization voltage lines VIL1 and VIL2, and the first voltage line VDDL. In this case, the first voltage line VDDL may be connected to the driving voltage supply wiring W11 (FIG. 3), and the second voltage line VSSL may be connected to the common voltage supply wiring W13 (FIG. 3).

The first voltage line VDDL may transfer the first power voltage VDD to the first transistor T1. The first initialization voltage line VIL1 may be configured to transfer a first initialization voltage Vint to the pixel circuit PC, wherein the first initialization voltage Vint initializes the first transistor T1. The second initialization voltage line VIL2 may be configured to transfer a second initialization voltage Vaint to the pixel circuit PC, wherein the second initialization voltage Vaint initializes the first electrode of the light-emitting diode LED.

The first transistor T1 may be electrically connected to the first voltage line VDDL through the fifth transistor T5, and may be electrically connected to the light- emitting diode LED through the sixth transistor T6. The first transistor T1 serves as a driving transistor, receives a data signal Dm, and supplies the driving current to the light-emitting diode LED according to a switching operation of the second transistor T2.

The second transistor T2 is a data-write transistor and is electrically connected to the scan signal line GWL and the data line DL. The second transistor T2 is electrically connected to the first voltage line VDDL through the fifth transistor T5. The second transistor T2 is turned on according to a scan signal GW transferred through the scan signal line GWL, and performs a switching operation of transferring a data signal Dm to a first node N1, the data signal Dm being transferred through the data line DL.

The third transistor T3 is electrically connected to the scan signal line GWL and is electrically connected to the light-emitting diode LED through the sixth transistor T6. The third transistor T3 may be turned on according to a scan signal GW to diode-connect the first transistor T1, wherein the scan signal GW is transferred through the scan signal line GWL.

The fourth transistor T4 serves as a first initialization transistor and is electrically connected to the initialization control line GIL and the first initialization voltage line VIL1. The fourth transistor T4 may be turned on according to an initialization control signal GI to initialize a voltage of the gate electrode of the first transistor T1 by transferring the first initialization voltage Vint to the gate electrode of the first transistor T1, wherein the initialization control signal GI is transferred through the initialization control line GIL. The initialization control signal GI may correspond to a scan signal of another pixel circuit located in a previous row of the relevant pixel circuit PC.

The fifth transistor T5 may be an operation control transistor, and the sixth transistor T6 may be an emission control transistor. The fifth transistor T5 and the sixth transistor T6 may be electrically connected to the emission control line EML, may be concurrently or substantially simultaneously turned on according to an emission control signal EM transferred through the emission control line EML, and may form a current path such that the driving current flows in a direction from the first voltage line VDDL to the light-emitting diode LED.

The seventh transistor T7 serves as a second initialization transistor and may be electrically connected to the bypass control line GBL, the second initialization voltage line VIL2, and the sixth transistor T6. The seventh transistor T7 is turned on according to a bypass control signal GB transferred through the bypass control line GBL, and is configured to transfer the second initialization voltage Vaint from the second initialization voltage line VIL2 to the first electrode of the light-emitting diode LED, thereby initializing the first electrode of the light-emitting diode LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel circuit PC is electrically connected to signal lines and voltage lines. The signal lines may include a gate line GL (FIG. 3), such as the scan signal line GWL, the bypass control line GBL, the initialization control line GIL, and the emission control line EML, and the data line DL. The voltage lines may include the first and second initialization voltage lines VIL1 and VIL2, a sustain voltage line VSL and the first voltage line VDDL. In this case, the first voltage line VDDL may be connected to the driving voltage supply wiring W11 (FIG. 3), and the second voltage line VSSL may be connected to the common voltage supply wiring W13 (FIG. 3).

The first voltage line VDDL may transfer the first power voltage VDD to the first transistor T1. The first initialization voltage line VIL1 may be configured to transfer the first initialization voltage Vint to the pixel circuit PC, wherein the first initialization voltage Vint initializes the first transistor T1. The second initialization voltage line VIL2 may be configured to transfer the second initialization voltage Vaint to the pixel circuit PC, wherein the second initialization voltage Vaint initializes the first electrode of the light-emitting diode LED. The sustain voltage line VSL may provide a sustain voltage VSUS to a second node N2, for example, the second electrode CE2 of the storage capacitor Cst during an initialization section and a data-write section.

The first transistor T1 may be connected to the first voltage line VDDL through the fifth transistor T5 and the eighth transistor T8, and may be electrically connected to the light-emitting diode LED through the sixth transistor T6. The first transistor T1 serves as the driving transistor, may receive a data signal Dm, and may supply the driving current to the light-emitting diode LED according to a switching operation of the second transistor T2.

The second transistor T2 is electrically connected to the scan signal line GWL and the data line DL and is electrically connected to the first voltage line VDDL through the fifth transistor T5 and the eighth transistor T8. The second transistor T2 may be turned on according to a scan signal GW transferred through the scan signal line GWL and may perform a switching operation of transferring a data signal Dm to the first node N1, wherein the data signal Dm is transferred through the data line DL.

The third transistor T3 is electrically connected to the scan signal line GWL and is electrically connected to the light-emitting diode LED through the sixth transistor T6. The third transistor T3 may be turned on according to a scan signal GW to compensate for a threshold voltage of the first transistor T1 by diode-connecting the first transistor T1, wherein the scan signal GW is transferred through the scan signal line GWL.

The fourth transistor T4 is electrically connected to the initialization control line GIL and the first initialization voltage line VIL1, turned on according to an initialization control signal GI transferred through the initialization control line GIL, and initializes a voltage of the gate electrode of the first transistor T1 by transferring the first initialization voltage Vint from the first initialization voltage line VIL1 to the gate electrode of the first transistor T1. The initialization control signal GI may correspond to a scan signal of another pixel circuit located in a previous row of the relevant pixel circuit PC.

The fifth transistor T5, the sixth transistor T6, and the eighth transistor T8 may be electrically connected to the emission control line EML, may be concurrently or substantially simultaneously turned on according to an emission control signal EM transferred through the emission control line EML, and may form a current path such that the driving current flows in a direction from the first voltage line VDDL to the light-emitting diode LED.

The seventh transistor T7 serves as a second initialization transistor, and may be electrically connected to the bypass control line GBL, the second initialization voltage line VIL2, and the sixth transistor T6. The seventh transistor T7 is turned on according to a bypass control signal GB transferred through the bypass control line GBL, and is configured to transfer the second initialization voltage Vaint from the second initialization voltage line VIL2 to the first electrode of the light-emitting diode LED, thereby initializing the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 is turned on according to a bypass control signal GB transferred through the bypass control line GBL, and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In one or more embodiments, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display panel depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting diode LED. The auxiliary capacitor Ca may reduce or prevent the likelihood of a black brightness rising when the sixth transistor T6 is turned off by storing and maintaining a voltage corresponding to a voltage difference between the first electrode of the light-emitting diode LED and the sustain voltage line VSL while the seventh transistor T7 and the ninth transistor T9 are turned on.

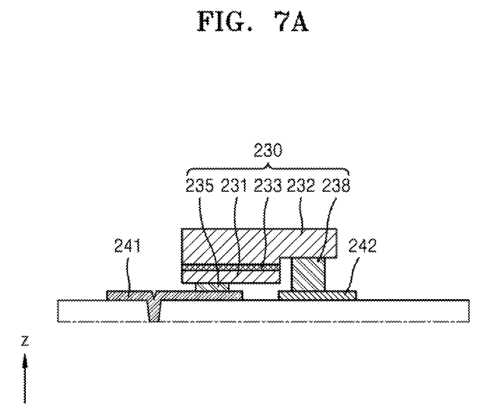

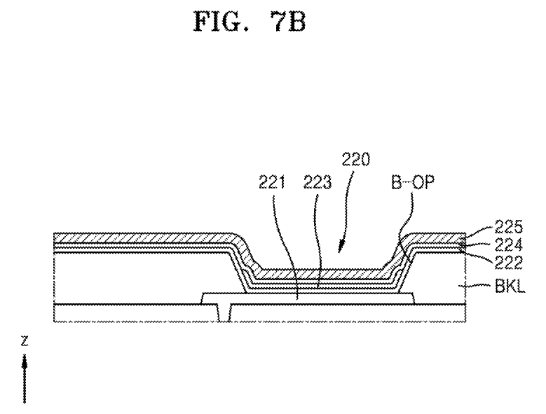

FIGS. 7A and 7B are schematic cross-sectional views of a light-emitting diode of the display panel according to one or more embodiments of the present disclosure.

Referring to FIG. 7A, the light-emitting diode LED (FIG. 6A) may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively electrically connected to a first electrode pad 241 and a second electrode pad 242 located on the same layer. The second electrode pad 242 may be a portion of the second voltage line VSSL (see FIG. 6A), or a conductive layer electrically connected to the second voltage line VSSL (see FIG. 6A).

In one or more embodiments, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and/or the like, and may be doped with a p-type dopant, such as Mg, Zn, Ca, Sr, or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and/or the like, and may be doped with an n-type dopant, such as Si, Ge, or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InₓAl_{y}Ga_{1-x-y}N (0≤x≤1, 0≤y≤1, 0≤x+y≤1), and may be formed in a single quantum-well structure or a multi quantum-well structure (MQW). In addition, the intermediate layer 233 may include a quantum-wire structure or a quantum-dot structure.

Although it is described in FIG. 7A that the first semiconductor layer 231 includes a p-type semiconductor layer, and the second semiconductor layer 232 includes an n-type semiconductor layer, the present disclosure is not limited thereto. In one or more other embodiments, the first semiconductor layer 231 may include an n-type semiconductor layer, and the second semiconductor layer 232 may include a p-type semiconductor layer.

Referring to FIG. 7B, the light-emitting diode LED (FIG. 6A) may be an organic light-emitting diode 220 including an organic material. The organic light-emitting diode 220 may include a first electrode 221 located on an insulating layer, a second electrode 225 facing the first electrode 221, and an emission layer 223 located between the first electrode 221 and the second electrode 225. A first functional layer 222 may be located between the first electrode 221 and the emission layer 223, and a second functional layer 224 may be located between the emission layer 223 and the second electrode 225.

The edge of the first electrode 221 may be covered by a bank layer BKL including an insulating material. The bank layer BKL may include an opening B-OP overlapping the central portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In one or more other embodiments, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In one or more other embodiments, the first electrode 221 may further include a layer on/under the reflective layer, the layer including ITO, IZO, ZnO, AZO, or In₂O₃.

The emission layer 223 may include a polymer organic material or a low-molecular weight organic material emitting light having a corresponding color (e.g., preset color). The first functional layer 222 may include a hole transport layer (HTL) and/or a hole injection layer (HIL). The second functional layer 224 may include an electron transport layer and/or an electron injection layer.

The second electrode 225 may include a conductive material having a low work function. As an example, the second electrode 225 may include a (semi-) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 225 may further include a layer on the (semi) transparent layer, the layer including ITO, IZO, ZnO, AZO, or In₂O₃.

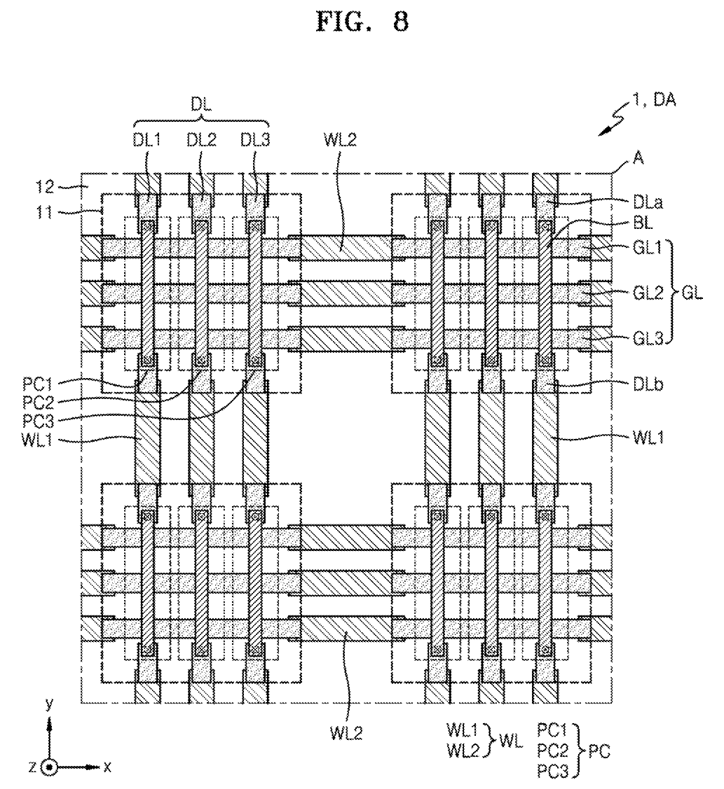

FIG. 8 is a schematic plan view of the display panel according to one or more embodiments of the present disclosure, and is a schematic view of a region A of the display panel of FIG. 3.

Referring to FIG. 8, the display area DA may include the plurality of first regions 11, and the second region 12 surrounding the plurality of first regions 11 (e.g., in plan view). The first region 11 may have an elongation that is less than an elongation of the second region 12. Accordingly, when the display panel 1 is stretched, the first region 11 may be less deformed than the second region 12. As described above, the first region 11 may be denoted by a low-deformation region (or low-deformation portion). In addition, the first region 11 is a region in which the light-emitting diodes are located and may be denoted by a pixel area or an emission area.

The second region 12 surrounds the first region 11, and may have an elongation that is greater than an elongation of the first region 11. The second region 12 may be a region in which main deformation occurs when the display panel is stretched or shrunk. Because the second region 12 is located between the plurality of first regions 11, the second region 12 may be denoted by a connector connecting the first regions 11. In addition, the second region 12 may be denoted by a main-deformation region (or a main-deformation portion) or a high-deformation region (or a high-deformation portion). The second region 12 is a region of the display area in which the light-emitting diodes are not located, and may be denoted by a non-pixel area or a non-emission area.

The pixel circuit PC for driving the light-emitting diode in each pixel may be located in the first region 11. As an example, a first pixel circuit PC1 of the red pixel PXr (FIG. 4), a second pixel circuit PC2 of the green pixel PXg (FIG. 4), and a third pixel circuit PC3 of the blue pixel PXb (FIG. 4) may be located in the first region 11. Each of the first pixel circuit PC1, the second pixel circuit PC2, and the third pixel circuit PC3 may include a transistor and a capacitor like the pixel circuit PC described with reference to FIGS. 6A to 6C.

Lines electrically connected to the pixel circuit PC may be located in the display area DA. The lines may include a voltage line or a signal line. In one or more embodiments, it is shown in FIG. 8 that each of the gate line GL and the data line DL are located in the first region 11. Each of the gate line GL and the data line DL may be electrically connected to the pixel circuit PC through a contact hole.

The gate line GL in FIG. 8 is a line for providing gate signals to a gate electrode of a transistor. In one or more embodiments, the gate line GL may include a first gate line GL1, a second gate line GL2, and a third gate line GL3. The first to third gate lines GL1, GL2, and GL3 extending in the first direction (e.g., the x direction) may be respectively connected to the pixel circuits PC arranged on the same row to transfer different gate signals. As an example, the gate line GL in FIG. 8 may be the scan signal line GWL, the bypass control line GBL, the initialization control line GIL, and/or the emission control line EML in FIG. 6B or 6C.

The data line DL in FIG. 8 is a line for providing data signals to each pixel circuit PC. The data line DL extending in the second direction (e.g., the y direction) may be electrically connected to the pixel circuits PC located in the same column. In one or more embodiments, the data line DL may include a first data line DL1 electrically connected to the first pixel circuit PC1, a second data line DL2 electrically connected to the second pixel circuit PC2, and a third data line DL3 electrically connected to the third pixel circuit PC3.

Two adjacent signal lines respectively located in two adjacent first regions 11 may be electrically connected to each other by the connection wiring WL. For example, two adjacent data lines DL respectively located in two adjacent first regions 11 may be electrically connected to each other by a first connection wiring WL1. The first connection wiring WL1 may be located in the second region 12 and may extend in the second direction (e.g., the y direction). Each of the data lines DL respectively located on the opposite sides with the first connection wiring WL1 therebetween may be connected to the first connection wiring WL1.

Two adjacent gate lines GL respectively located in two adjacent first regions 11 may be electrically connected to each other by a second connection wiring WL2. The second connection wiring WL2 may be located in the second region 12, and may extend in the first direction (e.g., the x direction). Each of the gate lines GL respectively located on the opposite sides with the second connection wiring WL2 therebetween may be connected to the second connection wiring WL2.

The gate line GL and the data line DL may cross each other in the first region 11. In one or more embodiments, the data line DL may include a first portion DLa and a second portion DLb separated from each other with the gate line GL therebetween, and a bridge line BL located between the first portion DLa and the second portion DLb. The first portion DLa and the second portion DLb may be electrically connected to each other by the bridge line BL.

The bridge line BL is located in a region where the data line DL and the gate line GL cross each other, and may connect the first portion DLa and the second portion DLb of the data line DL to each other. The bridge line BL may be located on a different layer from the first portion DLa and the second portion DLb. One end of the bridge line BL may be connected to the first portion DLa through a contact hole, and another end of the bridge line BL may be connected to the second portion DLb through a contact hole.

Although FIG. 8 describes that the data line DL is connected through the first portion DLa, the second portion DLb, and the bridge line BL, the present disclosure is not limited thereto. In one or more other embodiments, the gate line GL may be separated into a first portion and a second portion, and they may be connected through a bridge line.

The first and second connection wirings WL1 and WL2 located in the second region 12 may be stretched better, or more easily, than the gate line GL and the data line DL located in the first region 11. An elongation of each of the first and second connection wirings WL1 and WL2 may be greater than an elongation of each of the gate line GL and the data line DL.

Each of the gate line GL and the data line DL may include one or more materials selected among aluminum (Al), platinum (Pt), palladium (Pd), silver (Ag), magnesium (Mg), gold (Au), nickel (Ni), neodymium (Nd), iridium (Ir), chrome (Cr), lithium(Li), calcium (Ca), molybdenum (Mo), titanium (Ti), tungsten (W), and/or copper (Cu). In some embodiments, each of the gate line GL and the data line DL may be a single layer or a plurality of layers including the above metals. In one or more embodiments, each of the gate line GL and the data line DL may include a metal thin film including a triple layer having a structure of titanium (Ti)/aluminum (Al)/ titanium (Ti).

Although described below, the first and second connection wirings WL1 and WL2 may include a conductive composite material including a metal nanostructure, an elastic polymer, and/or elastomer. Accordingly, while the display panel 1 is stretched, high deformation may occur in the first and second connection wirings WL1 and WL2 and the second region 12.

Although it is shown in FIG. 8 that the gate line GL and the data line DL are respectively electrically connected to the first and second connection wirings WL1 and WL2, the present disclosure is not limited thereto. In one or more other embodiments, the first initialization voltage line VIL1, the second initialization voltage line VIL2, the sustain voltage line VSL, the first voltage line VDDL, or the second voltage line VSSL may each be located on the first region 11, and may be electrically connected to the connection wiring located in the second region 12.

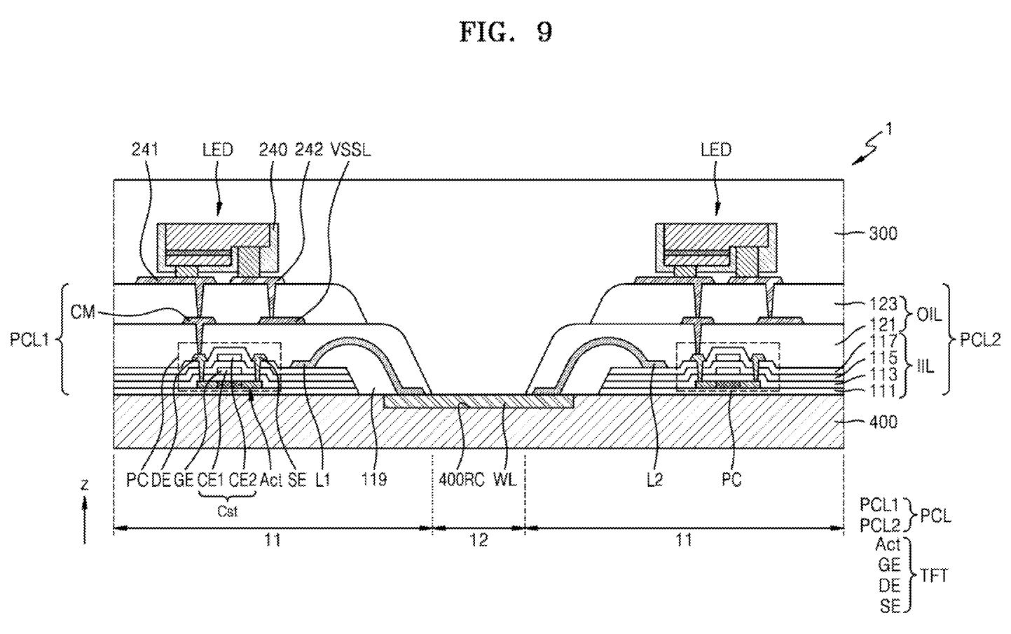

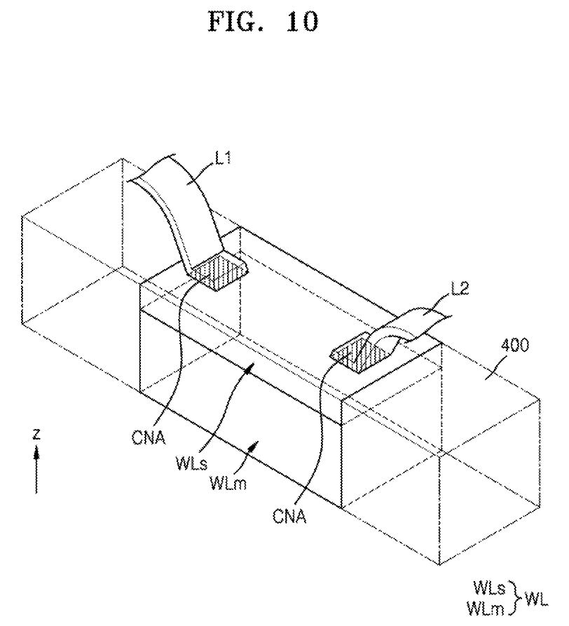

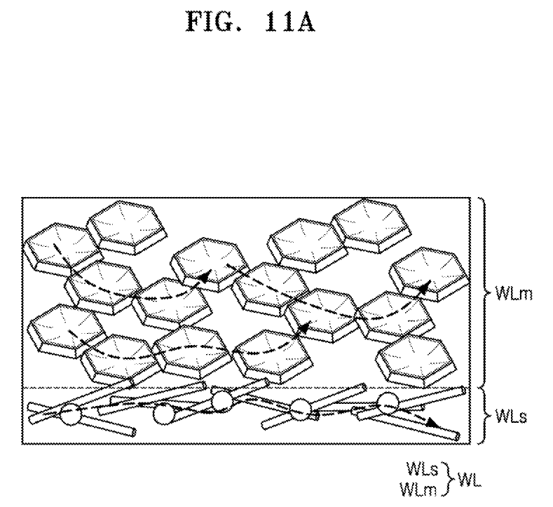

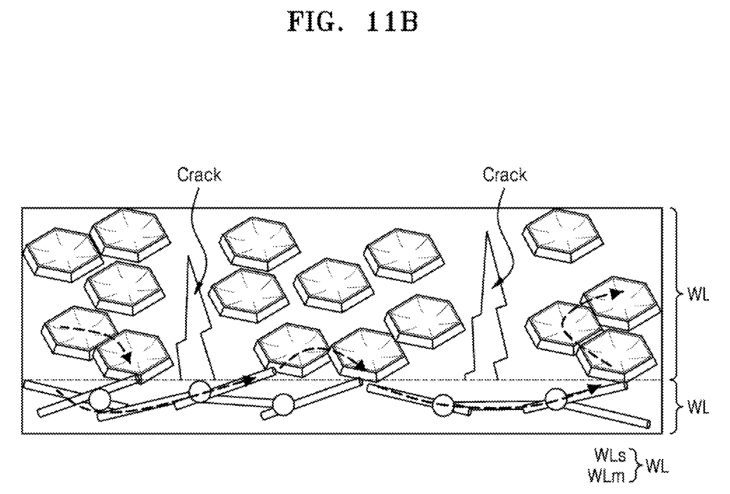

FIG. 9 is a schematic cross-sectional view of a portion of the display panel according to one or more embodiments of the present disclosure. FIG. 10 is an excerpted perspective view of a connection wiring of the display panel according to one or more embodiments of the present disclosure. FIGS. 11A and 11B are schematic views of a connection wiring of the display panel according to one or more embodiments of the present disclosure.

Referring to FIG. 9, as described above with reference to FIG. 8, the display panel 1 may include the first regions 11 and the second region 12 between the first regions 11. Because the elements of the display panel 1 are located on the base layer 400, when the display panel 1 includes the first region 11 and the second region 12, it may mean that the base layer 400 includes the first region 11 and the second region 12.

The display panel 1 may include a pixel circuit layer PCL located in each of adjacent two first regions 11, and the light-emitting diode LED on the pixel circuit layer PCL. The light-emitting diode LED shown in FIG. 9 may correspond to one of the first to third light-emitting diodes LED1, LED2, or LED3 shown in FIG. 5.

Each of the pixel circuit layers PCL may include an inorganic insulating stack IIL, the pixel circuit PC, and the organic insulating layer OIL. Hereinafter, for convenience of description, one of the pixel circuit layers PCL respectively located in the adjacent two first regions 11 is referred to as a first pixel circuit layer PCL1, and the other is referred to as a second pixel circuit layer PCL2.

Each of the first pixel circuit layer PCL1 and the second pixel circuit layer PCL2 may be located on the base layer 400. Each of the first pixel circuit layer PCL1 and the second pixel circuit layer PCL2 may be located on a first surface (e.g., an upper surface) of the base layer 400.

The base layer 400 may absorb stress that occurs while the display panel 1 is stretched. The base layer 400 may include an elastic polymer (or an elastic polymer material). The base layer 400 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or Ecoflex™ (Ecoflex™ being a registered trademark of Smooth-On, Inc., Macungie, PA).

Each of the first pixel circuit layer PCL1 and the second pixel circuit layer PCL2 may include the inorganic insulating stack IIL, the pixel circuit PC, and the organic insulating layer OIL. The inorganic insulating stack IIL may include a buffer layer 111, a gate-insulating layer 113, a first interlayer insulating layer 115, and a second interlayer insulating layer 117. The organic insulating layer OIL may include a first organic insulating layer 121 and a second organic insulating layer 123.

The first pixel circuit layer PCL1 and the second pixel circuit layer PCL2 may be located apart from each other. When the first pixel circuit layer PCL1 and the second pixel circuit layer PCL2 are apart from each other, it may denote that the inorganic insulating stack IIL, the pixel circuit PC, and the organic insulating layer OIL of the first pixel circuit layer PCL1 are respectively located apart from the inorganic insulating stack IIL, the pixel circuit PC, and the organic insulating layer OIL of the second pixel circuit layer PCL2.

The inorganic insulating stack IIL may be located in the first region 11, and may be omitted from the second region 12. The inorganic insulating stack IIL may have an isolated shape located in the first region 11. The inorganic insulating stacks IIL respectively located in the first regions 11 may be apart from each other in a plan view. As an example, the buffer layer 111, the gate-insulating layer 113, the first interlayer insulating layer 115, and the second interlayer insulating layer 117 of the first pixel circuit layer PCL1 may be respectively separated from the buffer layer 111, the gate-insulating layer 113, the first interlayer insulating layer 115, and the second interlayer insulating layer 117 of the second pixel circuit layer PCL2.

Likewise, the organic insulating layer OIL may be located in the first region 11, and may be omitted from the second region 12. The organic insulating layer OIL may have an isolated shape located in the first region 11. As an example, the first organic insulating layer 121 and the second organic insulating layer 123 of the first pixel circuit layer PCL1 may be respectively separated from the first organic insulating layer 121 and the second organic insulating layer 123 of the second pixel circuit layer PCL2.

As shown in FIG. 9, the buffer layer 111 may be located on the base layer 400, and the pixel circuit PC may be located on the buffer layer 111. The buffer layer 111 may include an inorganic insulating material, such as silicon oxide, silicon nitride, and silicon oxynitride.

A thin-film transistor TFT of the pixel circuit PC may include a semiconductor layer Act, a gate electrode GE, a source electrode SE, and a drain electrode DE. Although FIG. 9 shows a top-gate type thin-film transistor, in which the gate electrode GE is located on the semiconductor layer Act with the gate-insulating layer 113 therebetween is shown, the thin-film transistor TFT may be a bottom-gate type thin-film transistor in one or more other embodiments.

The semiconductor layer Act may include polycrystalline silicon. Alternatively, the semiconductor layer Act may include amorphous silicon, an oxide semiconductor, or an organic semiconductor. The gate electrode GE may include a metal thin film including a low-resistance metal material. The gate electrode GE may include a conductive material including molybdenum (Mo), aluminum (Al), copper (Cu), and titanium (Ti), and may have a single-layered structure or a multi-layered structure including the above materials. As an example, the gate electrode GE may include a metal thin film including a triple layer having a structure of titanium (Ti)/aluminum (Al)/ titanium (Ti).

The gate-insulating layer 113 between the semiconductor layer Act and the gate electrode GE may include an inorganic insulating material, such as silicon oxide, nitrogen oxide, silicon oxynitride, aluminum oxide, or titanium oxide. The gate-insulating layer 113 may include a single layer or a multi-layer including the above materials.

The source electrode SE and the drain electrode DE may be located on the same layer, for example, the second interlayer insulating layer 117 and may include the same material. The source electrode SE and the drain electrode DE may include a metal thin film including a low-resistance metal material. The source electrode SE and the drain electrode DE may each include a conductive material including molybdenum (Mo), aluminum (Al), copper (Cu), and titanium (Ti), and may include a single layer or a multi-layer including the above materials. As an example, like the gate electrode GE, the source electrode SE and the drain electrode DE may include a metal thin film including a triple layer having a structure of titanium (Ti)/aluminum (Al)/ titanium (Ti). The second interlayer insulating layer 117 may include an inorganic insulating material, such as silicon oxide, nitrogen oxide, silicon oxynitride, aluminum oxide, titanium oxide, and may include a single layer or a multi-layer including the above materials.

The storage capacitor Cst may include the first electrode CE1 and the second electrode CE2 overlapping each other with the first interlayer insulating layer 115 therebetween. The storage capacitor Cst may overlap the thin-film transistor TFT. With regard to this, it is shown in FIG. 9 that the gate electrode GE of the thin-film transistor TFT serves as the first electrode CE1 of the storage capacitor Cst. In one or more other embodiments, the storage capacitor Cst may not overlap the thin-film transistor TFT. The storage capacitor Cst may be covered by the second interlayer insulating layer 117.

The first interlayer insulating layer 115 may be located between the gate-insulating layer 113 and the second interlayer insulating layer 117. Each of the first interlayer insulating layer 115 and the second interlayer insulating layer 117 may include an inorganic insulating material, such as silicon oxide, nitrogen oxide, silicon oxynitride, aluminum oxide, titanium oxide, and may include a single layer or a multi-layer including the above materials.

The second electrode CE2 of the storage capacitor Cst may include a conductive material, and may include a single layer or a multi-layer. The second electrode CE2 may include a metal thin film including a low-resistance metal material. The second electrode CE2 may include a conductive material including molybdenum (Mo), aluminum (Al), copper (Cu), and titanium (Ti), and may have a single-layered structure or a multi-layered structure including the above materials. As an example, the second electrode CE2 may include a metal thin film including a triple layer having a structure of titanium (Ti)/aluminum (Al)/ titanium (Ti).

The first organic insulating layer 121 may be located on the second interlayer insulating layer 117. The second organic insulating layer 123 may be located on the first organic insulating layer 121. A connection electrode CM and the second voltage line VSSL may be located on the first organic insulating layer 121. The connection electrode CM may electrically connect the pixel circuit PC to the first electrode pad 241. The second voltage line VSSL may be electrically connected to the second electrode pad 242.

The connection electrode CM and the second voltage line VSSL may include a metal thin film including a low-resistance metal material. The connection electrode CM and the second voltage line VSSL may each include a conductive material including molybdenum (Mo), aluminum (Al), copper (Cu), and titanium (Ti), and may include a single layer or a multi-layer including the above materials. As an example, the connection electrode CM and the second voltage line VSSL may include a metal thin film including a triple layer having a structure of titanium (Ti)/aluminum (Al)/ titanium (Ti).

The first electrode pad 241 and the second electrode pad 242 may be located on the second organic insulating layer 123. The first electrode pad 241 may be electrically connected to the thin-film transistor TFT through the connection electrode CM between the first organic insulating layer 121 and the second organic insulating layer 123.

The light-emitting diode LED on the first electrode pad 241 and the second electrode pad 242 may be the same as the light-emitting diode LED described above with reference to FIG. 7A. In one or more other embodiments, the light-emitting diode LED may have the same structure as the structure of FIG. 7B. One surface of the light-emitting diode LED may be covered by the protective layer 240 including the organic insulating material.

A first line L1 (or a conductive line) may be a signal line or a voltage line electrically connected to the pixel circuit PC of the first pixel circuit layer PCL1. A second line L2 (or a conductive line) may be a signal line or a voltage line electrically connected to the pixel circuit PC of the second pixel circuit layer PCL2. In one or more embodiments, the first line L1 and the second line L2 may include the gate line GL (FIG. 8) or the data line DL (FIG. 8) described above with reference to FIG. 8. In one or more other embodiments, the first line L1 and the second line L2 may be the first voltage line VDDL or the second voltage line VSSL described with reference to FIG. 6A, or the first initialization voltage line VIL1, the second initialization voltage line VIL2, the sustain voltage line VSL, the first voltage line VDDL, or the second voltage line VSSL described with reference to FIGS. 6B and 6C.

Each of the first and second lines L1 and L2 may be located on the second interlayer insulating layer 117, and may extend on the connection wiring WL. A portion of the first line L1 may be located on a relevant second interlayer insulating layer 117. Another portion of the first line L1 may extend on the connection wiring WL beyond the inorganic insulating stack IIL and may directly contact the connection wiring WL. A portion of the first line L1 may be located between the second interlayer insulating layer 117 and the first organic insulating layer 121 in a third direction (e.g., a z direction), and another portion of the first line L1 may be located between a third organic insulating layer 119 described below and the second organic insulating layer 123. Likewise, a portion of the second line L2 may be located on a relevant second interlayer insulating layer 117, and another portion of the second line L2 may extend on the connection wiring WL and may directly contact the connection wiring WL. A portion of the second line L2 may be located between the second interlayer insulating layer 117 and the first organic insulating layer 121 in a third direction (e.g., a z direction), and another portion of the second line L2 may be located between the third organic insulating layer 119 described below and the second organic insulating layer 123.

On a plane, the inorganic insulating stack IIL of an isolated shape may form a step difference with respect to the upper surface of the base layer 400 as shown in FIG. 9. In one or more embodiments, as shown in FIG. 9, the organic insulating layer OIL may further include the third organic insulating layer 119 located to cover the lateral surface of the inorganic insulating stack IIL. The third organic insulating layer 119 may have a closed loop shape to cover the lateral surface of the inorganic insulating stack IIL in a plan view. The first and second lines L1 and L2 may pass across the upper surface of the relevant third organic insulating layer 119 and extend on the connection wiring WL.

As described above, the connection wiring WL may be located in the second region 12. In one or more embodiments, the connection wiring WL may be located on the lower surface of the pixel circuit layer PCL. In other words, the base layer 400 may include, or may define, a recess 400RC that is concave from the upper surface toward the lower surface, and the connection wiring WL may be present in the recess 400RC.

The connection wiring WL includes a first surface (e.g., the lower surface) facing the base layer 400, and a second surface (e.g., the upper surface) that is the opposite side of the first surface. The second surface (e.g., the upper surface) of the connection wiring WL may be located on the same surface as the upper surface of the base layer 400. Accordingly, the thickness of the base layer 400 overlapping the connection wiring WL may be less than the thickness of another portion of the base layer 400 not overlapping the connection wiring WL. That is, because the connection wiring WL has a structure embedded in the base layer 400, the base layer 400 may absorb stress that may be concentrated on the connection wiring WL while the display panel 1 is stretched.

Referring to FIGS. 10, 11A, and 11B, the connection wiring WL may include a structure in which a main connection wiring WLm and an auxiliary connection wiring WLs, which include different respective materials, are stacked. As described above, the connection wiring WL is located in the second region 12 and may include a material of high stretchability. As an example, the connection wiring WL may include a metal nanostructure.

As shown in FIG. 10, the connection wiring WL is located in the recess 400RC of the base layer 400, in which the main connection wiring WLm may be located in the recess 400RC, and the auxiliary connection wiring WLs may be located on the main connection wiring WLm. That is, the lower surface of the main connection wiring WLm may be in contact with the base layer 400, and the upper surface of the auxiliary connection wiring WLs may be in contact with the first line L1, the second line L2, and the protective layer 300. However, the connection wiring WL is not limited thereto, and the connection wiring WL may include a structure in which the main connection wiring WLm is located on the auxiliary connection wiring WLs in one or more other embodiments.

In one or more embodiments, the main connection wiring WLm and the auxiliary connection wiring WLs may respectively include nanostructures of different respective dimensions. As an example, the main connection wiring WLm may include a two-dimensional nanostructure, and the auxiliary connection wiring WLs may include at least one of a one-dimensional nanostructure or a zero-dimensional nanostructure.

In the present specification, a two-dimensional nanostructure may denote a nanostructure in which a size of two dimensions is remarkably greater than a size of one dimension. That is, a two-dimensional nanostructure may be a nanostructure in which an area defined by two dimensions is remarkably greater than a thickness. As an example, the two-dimensional nanostructure included in the main connection wiring WLm may include at least one of a nanoflake, a nano sheet, or a nanoplate. However, the two-dimensional nanostructure is not limited thereto, and any nanostructure may be used as far as the nanostructure is used as a two-dimensional nanostructure in the art.

In addition, in the present specification, a one-dimensional nanostructure may denote a nanostructure in which a size of one dimension is remarkably greater than a size of other two dimensions. That is, a one-dimensional nanostructure may be a nanostructure in which a length defined by one dimension is remarkably greater than the other dimensions. As an example, the one-dimensional nanostructure of the auxiliary connection wiring WLs may include at least one of a nanowire, a nanofiber, a nanotube, a nanorod, or a nanobelt. However, the one-dimensional nanostructure is not limited thereto, and any nanostructure may be used as far as the nanostructure is used as a one-dimensional nanostructure in the art.

Likewise, in the present specification, a zero-dimensional nanostructure may denote a structure in which all of sizes of three dimensions have a size of a nanometer level. That is, a zero-dimensional nanostructure may be a particle-shaped nanostructure with little three-dimensional extension (e.g., little extension in any direction). As an example, the zero-dimensional nanostructure included in the auxiliary connection wiring WLs may include a nanoparticle. However, the zero-dimensional nanostructure is not limited thereto and any nanostructure may be used as far as the nanostructure is used as a zero-dimensional nanostructure in the art.

In one or more embodiments, each of the main connection wiring WLm and the auxiliary connection wiring WLs may include a metal nanostructure. The main connection wiring WLm and the auxiliary connection wiring WLs may include a low-resistance metal, such as silver (Ag), copper (Cu), and/or nickel (Ni). In one or more embodiments, the main connection wiring WLm and the auxiliary connection wiring WLs may respectively include nanostructures of different dimensions from each other, and may include same or similar metal-based materials. As an example, the main connection wiring WLm may include Ag nanoflake as a two-dimensional nanostructure. The auxiliary connection wiring WLs may include Ag nanowire as a one-dimensional nanostructure, and may include Ag nanoparticle as a zero-dimensional structure.

In the case where the main connection wiring WLm and the auxiliary connection wiring WLs include the same metal-based materials, not only may an interface resistance between the main connection wiring WLm and the auxiliary connection wiring WLs be reduced, but also a bonding force between the main connection wiring WLm and the auxiliary connection wiring WLs may be improved.

However, the main connection wiring WLm and the auxiliary connection wiring WLs are not limited thereto, and in one or more other embodiments, because the main connection wiring WLm serves as a primary wiring, the main connection wiring WLm may include a low-resistance metal material, and the auxiliary connection wiring WLs may include a material with a relatively low conductivity but excellent stretchability. As an example, the main connection wiring WLm may include a metal nanostructure, such as Ag nanoflake, and the auxiliary connection wiring WLs may include a carbon-based nanostructure, such as a one-dimensional carbon nanotube and graphene.

Meanwhile, each of the main connection wiring WLm and the auxiliary connection wiring WLs may further include an elastic polymer material together with a metal nanostructure. In one or more embodiments, the elastic polymer material included in the main connection wiring WLm and the auxiliary connection wiring WLs may include the same material as the base layer 400 and/or the protective layer 300 described below. As an example, in the case where the base layer 400 includes PDMS, the main connection wiring WLm and the auxiliary connection wiring WLs may include PDMS in addition to the metal nanostructure. Alternatively, in the case where the base layer 400 includes polyurethane, the main connection wiring WLm and the auxiliary connection wiring WLs may include polyurethane in addition to the metal nanostructure.

Because the main connection wiring WLm includes the same elastic polymer material as the base layer 400, a bonding force between the main connection wiring WLm and the base layer 400 may be increased. Likewise, because the auxiliary connection wiring WLs includes the same elastic polymer material as the protective layer 300, a bonding force between the auxiliary connection wiring WLs and the protective layer 300 may be increased.

Here, FIG. 11A is a schematic view of the connection wiring WL in a non-stretched state, and FIG. 11B is a schematic view of the connection wiring WL in a stretched state. As in FIG. 11A, because both the main connection wiring WLm and the auxiliary connection wiring WLs include a metal nanostructure having conductivity, while the connection wiring WL is in a non-stretched state, both the main connection wiring WLm and the auxiliary connection wiring WLs may have excellent electrical characteristics. However, as in FIG. 11B, in the case where the connection wiring WL is stretched more than a corresponding level (e.g., preset level), cracks may occur in the surface of the main connection wiring WLm including two-dimensional nano structures. In this case, the auxiliary connection wiring WLs including one-dimensional nanostructures and zero-dimensional nanostructures may be located on one side of the main connection wiring WLm to serve as an auxiliary layer maintaining a conductive network.

For example, the main connection wiring WLm of the connection wiring WL may include Ag nanoflakes as two-dimensional nanostructures. That is, the main connection wiring WLm may include metal nanostructures having a thin, wide plate shape. The auxiliary connection wirings WLs of the connection wiring WL may be in a state in which one-dimensional nanostructures (e.g., nanowires) and zero-dimensional nanostructures are mixed. That is, the auxiliary connection wirings WLs may include metal nanostructures having a long and thin wire shape, and metal nanostructures having a spherical shape.

In the main connection wiring WLm including two-dimensional nanostructures, such as Ag nanoflakes, because each of the nanostructures has a wide contact area, a stack structure of nanostructures may be advantageous to be formed within the wire. That is, because a conductive network in the main connection wiring WLm may be easily formed within the wire, the main connection wiring WLm may be a wiring having excellent electrical characteristics while having stretchability. In one or more embodiments, the main connection wiring WLm may include Ag nanoflakes of about 80 wt% or more and about 100 wt% or less. The main connection wiring WLm may have electrical conductivity of about 10⁴ S/cm or more while securing elongation of about 50 % or more.

In the auxiliary connection wiring WLs including one-dimensional nano structures, such as Ag nanowires, because each nanostructure has a thin and long cylindrical shape, the nanostructures may be relatively flexibly located within the wire. That is, even when cracks occur due to stretching of the main connection wiring WLm, the auxiliary connection wiring WLs may maintain a conductive network within the connection wiring WL through the wire-shaped nanostructure.

For example, because the auxiliary connection wiring WLs further includes zero-dimensional nanostructures, such as Ag nanoparticles, the electrical characteristics of the connection wiring WL may be further improved. Zero-dimensional nanostructures, such as Ag nanoparticles may serve as Ag precursors. The Ag nanoparticles not only have excellent bonding characteristic with Ag nanowires, but also may grow through heat. That is, in the case where heat treatment is applied to the auxiliary connection wiring WLs, because the Ag nanoparticles may grow and increase contact areas of the nanostructures within the auxiliary connection wiring WLs, the conductive network within the connection wiring WL may be made robust.

That is, because the auxiliary connection wiring WLs having one-dimensional nanostructures and zero-dimensional nanostructures is located on one side of the main connection wiring WLm to connect crack portions that may occur in the surface of the main connection wiring WLm, resistance reduction due to cracks that may occur in the connection wiring WL may be reduced or minimized.

In addition, because the main connection wiring WLm is easy to form a conductive network, the main connection wiring WLm may be suitable to serve as the primary wiring. Accordingly, the thickness of the main connection wiring WLm may be greater than the thickness of the auxiliary connection wiring WLs. As an example, the thickness of the main connection wiring WLm may be a level of about 20 µm, and the thickness of the auxiliary connection wiring WLs may be a level of about 200 nm. That is, the thickness of the main connection wiring WLm and the thickness of the auxiliary connection wiring WLs may be a level of 100:1. However, the thickness of the main connection wiring WLm and the thickness of the auxiliary connection wiring WLs are not limited thereto, and may be changed by considering electrical characteristics and stretchability.

As a result, because the connection wiring WL in the display panel according to one or more embodiments of the present disclosure includes the main connection wiring WLm and the auxiliary connection wiring WLs having nanostructures of different respective dimensions, electrical stability of the display panel may be also secured as well as excellent stretchability. That is, because the auxiliary connection wiring WLs including the zero-dimensional nanostructures and the one-dimensional nanostructures is located on one side of the main connection wiring WLm having high conductivity, change in electrical characteristics of the connection wiring WL may be reduced or minimized even when the display panel is stretched.

For example, as described above, in the case where the main connection wiring WLm and the auxiliary connection wiring WLs include the same metal-based materials, a bonding force and the electrical characteristics of the main connection wiring WLm and the auxiliary connection wiring WLs may be improved while the auxiliary connection wiring WLs having a different kind of material is utilized as a conductive bridge.

Referring to FIG. 9 again, the light-emitting diode LED may be a relevant pixel circuit layer PCL. As an example, the light-emitting diode LED electrically connected to the pixel circuit PC of the first pixel circuit layer PCL1 may be located on the relevant first pixel circuit layer PCL1, and the light-emitting diode LED electrically connected to the pixel circuit PC of the second pixel circuit layer PCL2 may be located on the relevant second pixel circuit layer PCL2. One surface (e.g., a side surface(s)) of each light-emitting diode LED may be covered by the protective layer 240. The protective layer 240 may include an organic insulating material, such as polyimide.

The protective layer 300 may be located on the light-emitting diode LED and the connection wiring WL. The protective layer 300 may cover the light-emitting diode LED and the connection wiring WL. The protective layer 300 may absorb stress that otherwise may be transferred to the light-emitting diode LED and the connection wiring WL while the display panel 1 is stretched, and may planarize the upper surface of the display panel 1. The protective layer 300 may include an elastic polymer. As an example, the protective layer 300 may include at least one of thermoplastic polyurethane, polyester, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or Ecoflex™ (Ecoflex™ being a registered trademark of Smooth-On, Inc., Macungie, PA).

The protective layer 300 may directly contact the upper surface of the connection wiring WL, and may directly contact a portion of the upper surface of the base layer 400. In one or more embodiments, in the case where a material of the protective layer 300 is the same as a material of the base layer 400, because bonding force between the protective layer 300 and the base layer 400 may be increased, airtightness of the display panel 1 may be more effectively maintained.

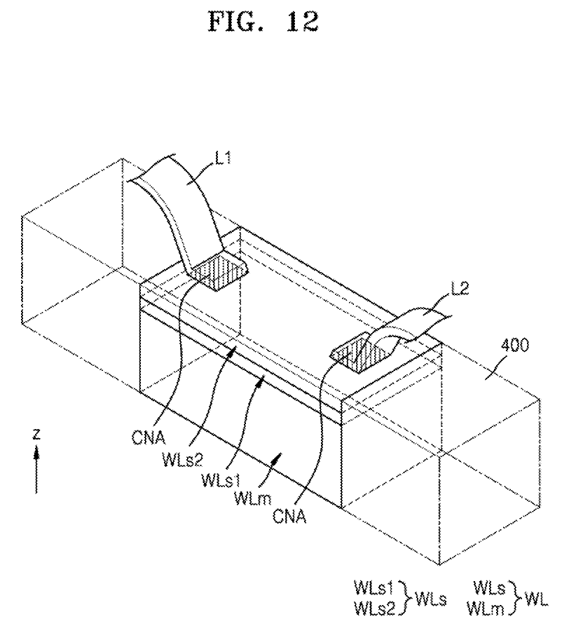

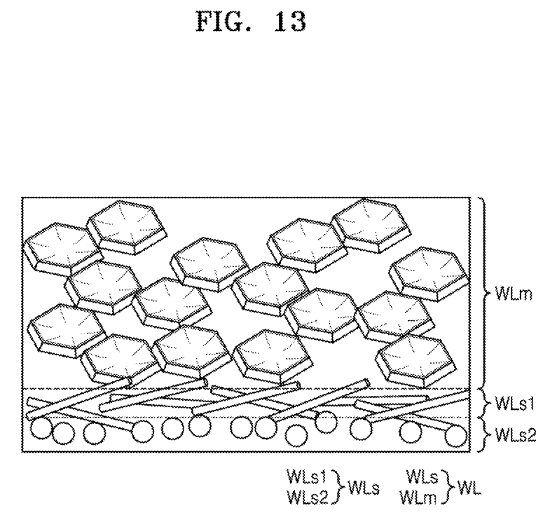

FIG. 12 is an excerpted perspective view of the connection wiring of the display panel according to one or more other embodiments of the present disclosure. FIG. 13 is a schematic cross-sectional view of the connection wiring of the display panel according to one or more other embodiments of the present disclosure. Referring to FIGS. 12 and 13, the other characteristics except for the characteristic of the auxiliary connection wiring WLs are the same as those described with reference to FIGS. 9 and 11B. Same reference numerals among elements of FIGS. 12 and 13 are replaced with those previously described with reference to FIGS. 9 to 11B, and differences are mainly described below.

Referring to FIGS. 12 and 13, the connection wiring WL may include a structure in which the main connection wiring WLm and the auxiliary connection wiring WLs including different respective materials are stacked. In this case, the auxiliary connection wiring WLs may include a first auxiliary connection wiring WLs1 and a second auxiliary connection wiring WLs2 respectively including nanostructures of different dimensions from each other.

As shown in FIG. 12, the connection wiring WL is located in the recess 400RC (FIG. 9) of the base layer 400, in which the main connection wiring WLm, the first auxiliary connection wiring WLs1, and the second auxiliary connection wiring WLs2 may be sequentially located in the recess 400RC (FIG. 9). That is, the first auxiliary connection wiring WLs1 may be located on the main connection wiring WLm, and the second auxiliary connection wiring WLs2 may be located on the first auxiliary connection wiring WLs1. Accordingly, the lower surface of the main connection wiring WLm may be in contact with the base layer 400, and the upper surface of the second auxiliary connection wiring WLs2 may be in contact with the first line L1, the second line L2, and the protective layer 300 (FIG. 9).

The main connection wiring WLm, the first auxiliary connection wiring WLs1, and the second auxiliary connection wiring WLs2 may respectively include nanostructures of different dimensions from each other. In one or more embodiments, the main connection wiring WLm may include two-dimensional nanostructures, the first auxiliary connection wiring WLs1 may include one-dimensional nanostructures, and the second auxiliary connection wiring WLs2 may include zero-dimensional nanostructures. The two-dimensional nanostructure may include at least one of a nanoflake, a nanosheet, or a nanoplate. The one-dimensional nanostructure may include at least one of a nanowire, a nanofiber, a nanorod, or a nanobelt, and the zero-dimensional nanostructure may include a nanoparticle.

In one or more embodiments, the main connection wiring WLm, the first auxiliary connection wiring WLs1, and the second auxiliary connection wiring WLs2 may respectively have different dimensional nanostructures, and may have the same metal-based materials. As an example, the main connection wiring WLm may include Ag nanoflakes, the first auxiliary connection wiring WLs1 may include Ag nanowires, and the second auxiliary connection wiring WLs2 may include Ag nanoparticles.

Meanwhile, each of the main connection wiring WLm, the first auxiliary connection wiring WLs1, and the second auxiliary connection wiring WLs2 may further include an elastic polymer material together with a metal nanostructure. In one or more embodiments, the elastic polymer material included in the main connection wiring WLm, the first auxiliary connection wiring WLs1, and the second auxiliary connection wiring WLs2 may include the same material as the base layer 400 and/or the protective layer 300 (FIG. 9). As an example, in the case where the base layer 400 includes PDMS, the main connection wiring WLm, the first auxiliary connection wiring WLs1, and the second auxiliary connection wiring WLs2 may include PDMS in addition to the metal nanostructure.

As in FIG. 13, because the main connection wiring WLm includes Ag nanoflakes, the conductive network may be easily formed within the wiring, so that the main connection wiring WLm may have excellent electrical characteristics with stretchability. Because the first auxiliary connection wiring WLs1 includes Ag nanowires, the first auxiliary connection wiring WLs1 may maintain the conductive network within the connection wiring WL even when cracks occur in the main connection wiring WLm. Because the second auxiliary connection wiring WLs2 includes Ag nanoparticles, the second auxiliary connection wiring WLs2 may make the conductive network within the connection wiring WL more robust.

As a result, because the connection wiring WL in the display panel according to one or more embodiments of the present disclosure includes the main connection wiring WLm, the first auxiliary connection wiring WLs1, and the second auxiliary connection wiring WLs2 respectively having nanostructures of different dimensions from each other, electrical stability of the display panel may be also secured as well as excellent stretchability.

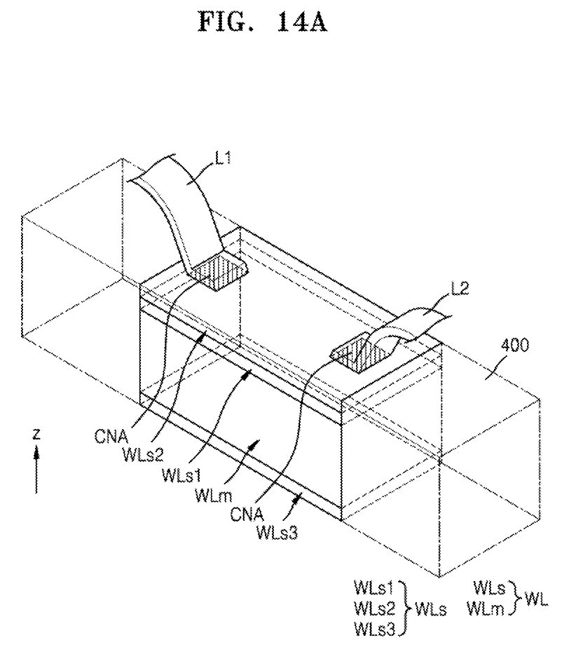

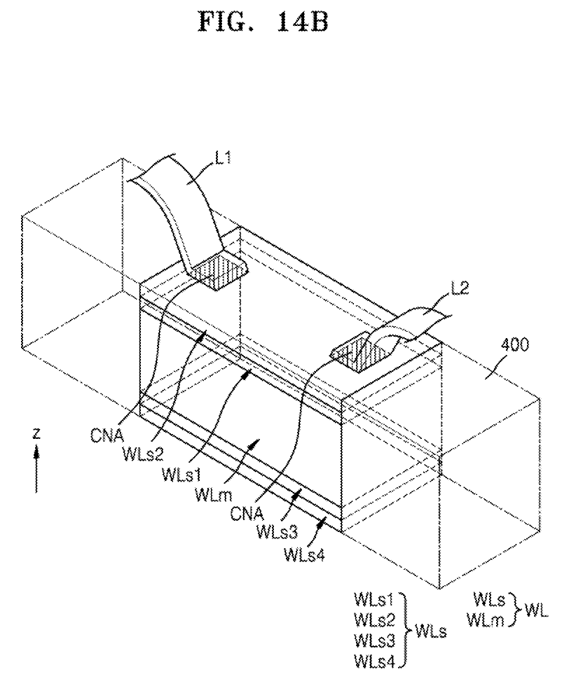

FIGS. 14A and 14B are excerpted cross-sectional views of the connection wiring of the display panel according to one or more other embodiments of the present disclosure. Referring to FIGS. 14A and 14B, the other characteristics except for the characteristic of the auxiliary connection wiring WLs are the same as those described with reference to FIGS. 9 and 13. Same reference numerals among elements of FIGS. 14A and 14B are replaced with those previously described with reference to FIGS. 9 to 13, and differences are mainly described below.

First, the connection wiring WL may include a structure in which the main connection wiring WLm and the auxiliary connection wiring WLs including different materials from each other are stacked. In this case, the auxiliary connection wiring WLs may include the first auxiliary connection wiring WLs1 and the second auxiliary connection wiring WLs2 respectively including nanostructures of different dimensions from each other. In one or more embodiments, the auxiliary connection wiring WLs may further include a third auxiliary connection wiring WLs3 including a different material from the main connection wiring WLm, the first auxiliary connection wiring WLs1, and the second auxiliary connection wiring WLs2.

The third auxiliary connection wiring WLs3 may include a material having a lower conductivity than, while having higher stretchability than, the first auxiliary connection wiring WLs1 and the second auxiliary connection wiring WLs2 including the metal nanostructures. In one or more embodiments, the third auxiliary connection wiring WLs3 may include a carbon-based nanostructure. The third auxiliary connection wiring WLs3 may include at least one of a one-dimensional carbon nanostructure or a two-dimensional nanostructure. The third auxiliary connection wiring WLs3 may include, as a one-dimensional carbon nanostructure, at least one of a carbon nanotube, a carbon nanowire, a carbon nanofiber, a carbon nanobelt, or a carbon nanorod. The third auxiliary connection wiring WLs3 may include at least one of graphene, graphene oxide, graphene nanoplate, or carbon nanosheet among two-dimensional nanostructures.

As shown in FIG. 14A, the connection wiring WL is located in the recess 400RC (FIG. 9) of the base layer 400, in which the third auxiliary connection wiring WLs3, the main connection wiring WLm, the first auxiliary connection wiring WLs1, and the second auxiliary connection wiring WLs2 may be sequentially located in the recess 400RC (FIG. 9). That is, the third auxiliary connection wiring WLs3 may be located under the main connection wiring WLm, and the first auxiliary connection wiring WLs1 and the second auxiliary connection wiring WLs2 may be located on the main connection wiring WLm.

Next, referring to FIG. 14B, the connection wiring WL may include a structure in which the main connection wiring WLm and the auxiliary connection wiring WLs including different materials from each other are stacked. In this case, the auxiliary connection wiring WLs may include a first auxiliary connection wiring WLs1 and a second auxiliary connection wiring WLs2 respectively including nanostructures of different dimensions from each other. In one or more embodiments, the auxiliary connection wiring WLs may further include a third auxiliary connection wiring WLs3 and a fourth auxiliary connection wiring WLs4, each of which including a different material from the main connection wiring WLm, the first auxiliary connection wiring WLs1, and the second auxiliary connection wiring WLs2.

The third auxiliary connection wiring WLs3 and the fourth auxiliary connection wiring WLs4 may include a material having a lower conductivity, while having higher stretchability, than the first auxiliary connection wiring WLs1 and the second auxiliary connection wiring WLs2 including the metal nanostructures. In one or more embodiments, the third auxiliary connection wiring WLs3 and the fourth auxiliary connection wiring WLs4 may include carbon-based nanostructures. In one or more embodiments, the third auxiliary connection wiring WLs3 may include carbon-based two-dimensional nanostructures, and the fourth auxiliary connection wiring WLs4 may include carbon-based one-dimensional nanostructures.

The third auxiliary connection wiring WLs3 may include at least one of graphene, graphene oxide, graphene nanoplate, or carbon nanosheet among two-dimensional nanostructures. The fourth auxiliary connection wiring WLs4 may include, as a one-dimensional carbon nanostructure, at least one of a carbon nanotube, a carbon nanowire, a carbon nanofiber, a carbon nanobelt, or a carbon nanorod. The third auxiliary connection wiring WLs3 may include at least one of graphene, graphene oxide, graphene nanoplate, or carbon nanosheet among two-dimensional nanostructures.

As shown in FIG. 14B, the connection wiring WL is located in the recess 400RC (FIG. 9) of the base layer 400, in which the fourth auxiliary connection wiring WLs4, the third auxiliary connection wiring WLs3, the main connection wiring WLm, the first auxiliary connection wiring WLs1, and the second auxiliary connection wiring WLs2 may be sequentially located in the recess 400RC (FIG. 9). That is, the third auxiliary connection wiring WLs3 and the fourth auxiliary connection wiring WLs4 may be located under the main connection wiring WLm, and the first auxiliary connection wiring WLs1 and the second auxiliary connection wiring WLs2 may be located on the main connection wiring WLm.

As in FIGS. 14A and 14B, the main connection wiring WLm may include Ag nanoflakes to have excellent electrical characteristics with stretchability. Because the first auxiliary connection wiring WLs1 and the second auxiliary connection wiring WLs2 respectively include nanowires and Ag nanoparticles, a conductive network within the connection wiring WL may be maintained. In addition, the third auxiliary connection wiring WLs3 and/or the fourth auxiliary connection wiring WLs4 located under the main connection wiring WLm may have a relatively lower conductivity than the first auxiliary connection wiring WLs1 and the second auxiliary connection wiring WLs2 including the metal nanostructures, but may be advantageous in an aspect of stretchability.

As a result, in the display panel according to one or more embodiments of the present disclosure, because the auxiliary wiring including metal-based nanostructures is located on one side of the main connection wiring WLm, and the auxiliary wiring including carbon-based nanostructures is located on another side, electrical stability and excellent stretchability of the display panel may be efficiently and concurrently or substantially simultaneously implemented.

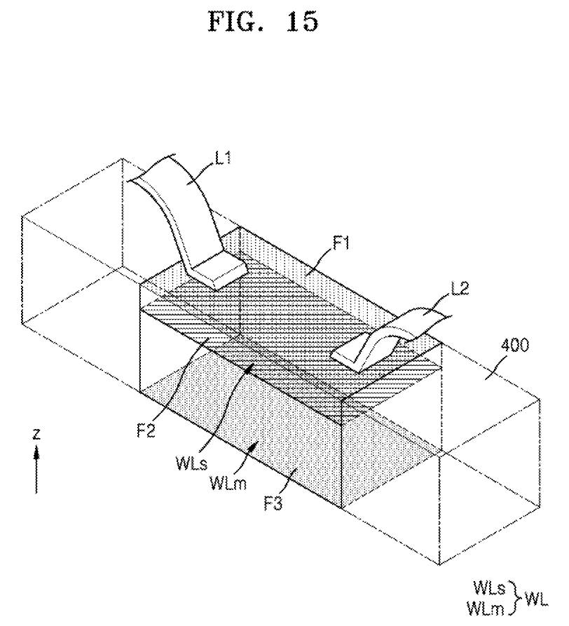

FIG. 15 is an excerpted perspective view of the connection wiring of the display panel according to one or more other embodiments of the present disclosure. Referring to FIG. 15, the characteristics except for the characteristic of the connection wiring WL are generally the same as those described with reference to FIGS. 9 and 11B. Same reference numerals among elements of FIG. 15 are replaced with those previously described with reference to FIGS. 9 to 11B, and differences are mainly described below.

As shown in FIG. 15, the connection wiring WL is located in the recess 400RC (FIG. 9) of the base layer 400, in which the main connection wiring WLm and the auxiliary connection wiring WLs may be sequentially located in the recess 400RC. Accordingly, the lower surface of the main connection wiring WLm may be in contact with the base layer 400, the upper surface of the main connection wiring WLm may be in contact with the lower surface of the auxiliary connection wiring WLs, and the upper surface of the auxiliary connection wiring WLs may be in contact with the protective layer 300 (FIG. 9). In this case, an interface between the auxiliary connection wiring WLs and the protective layer 300 (FIG. 9) may be referred to as a first interface F1, an interface between the auxiliary connection wiring WLs and the main connection wiring WLm may be referred to as a second interface F2, and an interface between the main connection wiring WLm and the base layer 400 may be referred to as a third interface F3.

In one or more embodiments, the first to third interfaces F1, F2, and F3 may be surface-treated to increase bonding force of the connection wiring WL, the base layer 400, and the protective layer 300 (FIG. 9). As an example, each of the first to third interfaces F1, F2, and F3 may be surface-treated through polymer treatment. Here, when the first to third interfaces F1, F2, and F3 are surface-treated through polymer treatment, it may mean that self-assembled monolayers (SAM) are formed in the first to third interfaces F1, F2, and F3. When the self-assembled monolayers are formed in the first to third interfaces F1, F2, and F3, molecules with corresponding functional groups are aligned on the surface to form a single layer structure, and the surface may be modified and the interfacial bonding force may be improved.

Alternatively, each of the first to third interfaces F1, F2, and F3 may be surface-treated through plasma treatment. Plasma treatment is a surface treatment technology that uses gas in a plasma state to change the surface of a material, and may use methods, such as low-pressure plasma and radio-frequency plasma. When the first to third interfaces F1, F2, and F3 are surface-treated through plasma treatment, the surfaces of the first to third interfaces F1, F2, and F3 are modified and the interfacial bonding force may be improved.

That is, in the display panel according to one or more embodiments of the present disclosure, because the connection wiring WL includes surface-treated interfaces, not only bonding force between the main connection wiring WLm and the auxiliary connection wiring WLs, but also bonding force between the connection wiring WL and the base layer 400, and bonding force between the connection wiring WL and the protective layer 300 may be increased together. The display panel according to one or more embodiments of the present disclosure may more efficiently maintain airtightness of the display panel through surface treatment process.

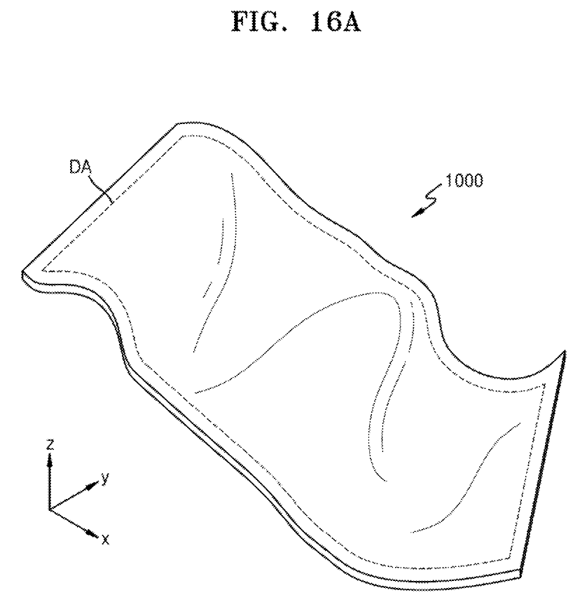

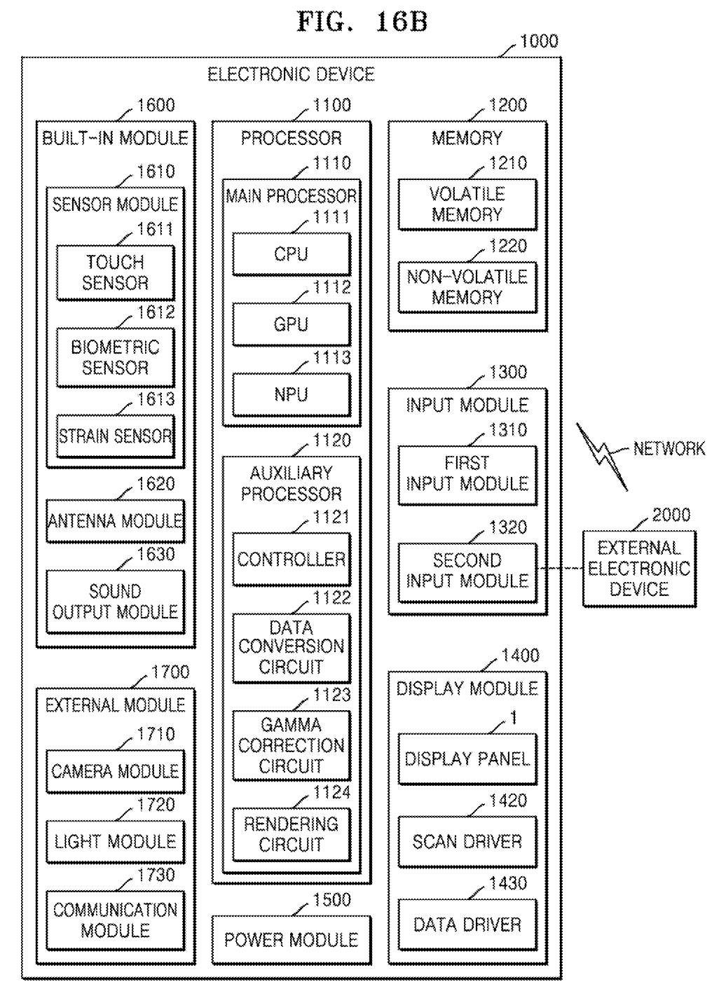

FIG. 16A is a schematic perspective view of an electronic device 1000 including a display panel according to one or more embodiments, and FIG. 16B is a schematic block diagram of the electronic device 1000 including the display panel 1 according to one or more embodiments.

Referring to FIG. 16A, the electronic device 1000 is freely deformed three-dimensionally, and may provide a three-dimensional image surface through the display area DA. When the electronic device 1000 is freely deformed three-dimensionally, it is distinguished from an operation of an electronic device having a rollable display panel, such as a case where a portion of a rolled-up display area is visible to a user, and then another portion of the rolled-up display area is unfolded so that the entire display area is visible to the user (or a case where the entire unfolded display area is visible to the user and then the display area is rolled-up so that only a portion of the display area is visible to the user). The electronic device 1000 according to embodiments of the present disclosure may represent deformation, such as a case where the area of the entire display area DA increases or decreases again while the electronic device 1000 is deformed in the x direction, y direction, and/or z direction.

Referring to FIG. 16B, the electronic device 1000 may include a processor 1100, a memory 1200, an input module 1300, a display module 1400, a power module 1500, a built-in module 1600, and an external module 1700. According to one or more embodiments, in the electronic device 1000, at least one of the elements may be omitted, or one or more other elements may be added. According to one or more embodiments, some (e.g., the built-in module 1600) of the elements may be integrated into another element (e.g., the display module 1400).

The processor 1100 may control at least one other element (e.g., hardware or software element) of the electronic device 1000 connected to the processor 1100 by executing software, and perform various data processes or operations. According to one or more embodiments, as at least some of data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one of a central processing unit (CPU) 1111 or an application processor (AP). The main processor 1110 may further include at least one of a graphic processing unit (GPU) 1112, a communication processor (CP), or an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above, but is not limited to the examples described above. The artificial intelligence models may additionally or alternatively include a software structure in addition to a hardware structure. At least two of the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals required for driving the display module 1400.

The auxiliary processor 1120 may further include a data processor (e.g., a data-processing circuit), such as a data conversion circuit 1122, a gamma correction circuit 1123, and a renderer (e.g., a rendering circuit) 1124. The data conversion circuit 1122 may receive image data from the controller 1121, correct image data such that images are displayed at desired brightness according to characteristics of the electronic device 1000, a user’s settings, or the like, or convert image data to reduce power consumption or compensate for an afterimage. The gamma correction circuit 1123 may convert image data, a gamma reference voltage, or the like such that images displayed by the electronic device 1000 have desired gamma characteristics. The renderer 1124 may receive image data from the controller 1121, and render the image data by considering the pixel configuration of the display panel 1 applied to the electronic device 1000. At least one of the data conversion circuit 1122, the gamma correction circuit 1123, or the renderer 1124 may be integrated into another element (e.g., the main processor 1110 or controller 1121). In one or more embodiments, the auxiliary processor 1120 may be integrated into a data driver 1430.

The memory 1200 may store various data and input data or output data for commands related thereto, wherein the various data are used by at least one element (e.g., the processor 1100 or the sensor module 1610) of the electronic device 1000. The memory 1200 may include at least one of the volatile memory 1210 or the non-volatile memory 1220.

The input module 1300 may receive commands or data from the outside (e.g., a user or an external electronic device 2000) of the electronic device 1000, wherein the commands or data are to be used by the element (e.g., the processor 1100, the sensor module 1610, or a sound output module 1630) of the electronic device 1000.

The input module 1300 may include a first input module 1310 to which commands or data from a user are input, and a second input module 1320 to which commands or data from the external electronic device 2000 are input.

The first input module 1310 may include a microphone, a mouse, a keyboard, or a pen (e.g., a passive pen or active pen). The first input module 1310 may include a mechanical input means, such as buttons, a dome switch, a jog wheel, a jog switch, and/or the like, or a touch input means located on the lower surface or the lateral surface of the electronic device 1000. The touch input means may include a touchscreen layer of the display panel 1.

The second input module 1320 may be connected to various kinds of external electronic devices 2000 connected to the electronic device 1000 via wires or wirelessly. In one or more embodiments, the second input module 1320 may include a high definition multimedia interface (HDMI), a universal serial bus (USB) interface, a secure digital (SD) card interface, or an audio interface. The second input module 1320 may include a connector that may physically connect the electronic device 1000 to the external electronic device 2000, wherein the connector includes an HDMI connector, a USB connector, an SD card connector, or an audio connector (e.g., a headphone connector). The electronic device 1000 may perform appropriate control related to the connected external electronic device 2000 in response to the external electronic device 2000 being connected to the second input module 1320.

The display module 1400 provides a user with visual information. The display module 1400 may include the display panel 1, a scan driver 1420, and the data driver 1430.

The display panel 1 displays (outputs) information processed by the electronic device 1000. The display panel 1 may display execution screen information of an application driven in the electronic device 1000, or user interface (UI) and graphic user interface (GUI) information corresponding to the execution screen information.

The scan driver 1420 may be mounted on the display panel 1 as a driving chip. Alternatively, the scan driver 1420 may be directly formed on the display panel 1. As an example, the scan driver 1420 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display panel 1. The scan driver 1420 receives control signals from the controller 1121, and outputs scan signals to the display panel 1 in response to control signals.

The display panel 1 may further include an emission control driver. The emission control driver outputs an emission control signal to the display panel 1 in response to a control signal received from the controller 1121. The emission control driver may be formed separately from the scan driver 1420, or may be integrated in the scan driver 1420.

The data driver 1430 receives a control signal from the controller 1121, converts image data into a data voltage in the form of an analog voltage in response to a control signal, and outputs data voltages to the display panel 1.

The data driver 1430 may be integrated into some elements of the auxiliary processor 1120. As an example, the data driver 1430 may be provided in a timing controller embedded driver integrated circuit (IC) including the controller 1121.

The data driver 1430 may be mounted on the display panel 1 as a driving chip. Alternatively, the data driver 1430 may be directly formed on the display panel 1. In the case where the scan driver 1420 and the data driver 1430 are directly formed on the display panel 1, the display panel 1 may be actually the display module 1400.

The power module 1500 supplies power to the elements of the electronic device 1000. The power module 1500 may include a battery charging a power voltage. In addition, the power module 1500 has a connection port, and the connection port may be included in the second input module 1320 to which an external charger that supplies power to charge the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC supplies power optimized for each of the elements of the electronic device 1000.

The electronic device 1000 may further include the built-in module 1600 and the external module 1700. The built-in module 1600 may include the sensor module 1610, an antenna module 1620, and the sound output module 1630. The external module 1700 may include a camera module 1710, a light module1720, and/or the communication module 1730.

The sensor module 1610 may include touch electrodes of the touchscreen layer of the display panel 1, and a touch sensor driver. The sensor module 1610 may sense an input due to a user’s body or an input due to a pen, and generate an electrical signal or a data value corresponding to the input. The sensor module 1610 may include at least one of a touch sensor 1611, a biometric sensor 1612, or a strain sensor 1613.

The touch sensor 1611 may generate a data value corresponding to coordinate information of an input due to a user’s body (e.g., fingers and/or the like) or an input due to a pen. The touch sensor 1611 may generate, as data values, changes in electrostatic capacity, pressure, or electromagnetism due to an input.

The biometric sensor 1512 may generate data values that recognize a portion of the user's body (e.g., fingerprints, irises, face, and/or the like) or generate data values corresponding to body information (e.g., a blood pressure, moisture, a heart rate, a body composition, and/or the like). The biometric sensor 1512 may use an optical method, an ultrasonic method, or a capacitive method.

The strain sensor 1613 may include layers, patterns, or wirings in which a measurable physical quantity changes according to the stretching of the display panel 1. As an example, the strain sensor 1613 may include layers, patterns, or wirings in which a pressure, a resistance, and/or a capacitance changes due to the stretching of the display panel 1. In one or more other embodiments, the strain sensor 1613 may include optical layers or optical patterns in which a transmittance and/or reflectivity changes due to the stretching of the display panel 1.

The electronic device 1000 may improve the quality of images implemented by the display panel 1 or control the display panel 1 based on physical quantity changes due to the stretching of the display panel 1 measured by the strain sensor 1613. Control operations of the display panel 1 may include operations, such as displaying an operation image for protecting the display panel 1, blocking voltages for driving the display panel 1, or stopping a stretching operation of the display panel 1.

In one or more embodiments, at least one of the touch sensor 1611, the biometric sensor 1612, or the strain sensor 1613 may be built into the display panel 1. As an example, at least one of the touch sensor 1611, the biometric sensor 1612, or the strain sensor 1613 may be formed during a process that is successive to the process of forming the pixel driver portion (e.g., pixel-driving circuit portion) and/or the light-emitting element of the display panel 1. Accordingly, the display panel 1 may serve as one of the input modules 1300 that provide an input interface between the electronic device 1000 and a user, and concurrently or substantially simultaneously serve as the display module 1400 that provides an output interface between the electronic device 1000 and a user.

In one or more embodiments, at least two of the touch sensor 1611, the biometric sensor 1612, and the strain sensor 1613 may be formed to be integrated in one sensing panel through the same process. In one or more embodiments, although the sensing panel may be located between the display panel 1 and a window cover located on a front surface of the display panel 1, the disclosure is not limited thereto.

The antenna module 1620 may include at least one antenna for transmitting signals or power to the outside or receiving signals or power from the outside. In one or more embodiments, the communication module 1730 may transmit signals to an external electronic device or receive signals from an external electronic device through an antenna suitable for a communication method. An antenna pattern of the antenna module 1620 may be integrated in one element (e.g., the display panel 1) of the display module 1400 or the biometric sensor 1612.

The sound output module 1630 is a device for outputting sound signals to the outside of the electronic device 1000, and may output sound data received from the communication module 1730 or stored in the memory 1200 during call signal reception, a communication mode or recording mode, a voice recognition mode, a broadcasting reception mode, and/or the like. The sound output module 1630 may output sound signals related to a function (e.g., a call signal reception tone, a message reception tone, and/or the like) performed by the electronic device 1000. The sound output module 1630 may include a receiver and a speaker. At least one of the receiver or the speaker may be a sound generator that is attached on the backside of the display panel 1 and vibrates the display panel 1 to output sounds. The sound generator may be a piezoelectric element or a piezoelectric actuator that contracts and expands according to electrical signals, or an exciter that generates magnetic force by using a voice coil to vibrate the display panel 1.

The camera module 1710 may capture still images and moving images. In one or more embodiments, the camera module 1710 may include at least one lens, an image sensor, or an image signal processor. The camera module 1710 may further include an infrared camera that may measure whether a user is present, a user’s position, a user’s gaze, and/or the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and/or the like. The light module 1720 may include a light-emitting diode or a xenon lamp. The light module 1720 may emit light of a single color or multiple colors to the front side or backside of the electronic device 1000. The light module 1720 may operate in cooperation with the camera module 1710 or independently.

The communication module 1730 may establish a wired or wireless communication channel between the electronic device 1000 and the external electronic device 2000, and perform communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may transmit and receive wireless signals on the Internet using at least one of a wireless LAN) (WLAN), wireless-fidelity (Wi-Fi® (Wi‑Fi® being a registered trademark of the non-profit Wi-Fi Alliance)), Wi-Fi® direct, and digital living network alliance (DLNA) technologies. In addition, the communication module 1730 may support short-range communication using at least one of Bluetooth™ (Bluetooth™ being a registered trademark of Bluetooth Sig, Inc., Kirkland, WA), RFID radio frequency identification (RFID), infrared data association (IrDA), ultra-wideband (UWB), Zigbee® (Zigbee® being a registered trademark of CONNECTIVITY STANDARDS ALLIANCE, Davis, CA), near field communication (NFC), Wi-Fi ®, Wi-Fi Direct^{TM} (Wi-Fi Direct^{TM} being a registered trademark of the non-profit Wi-Fi Alliance), or wireless universal serial bus (USB) technologies. The above-described various kinds of communication modules 1730 may be implemented in one chip or respectively implemented as separate chips.

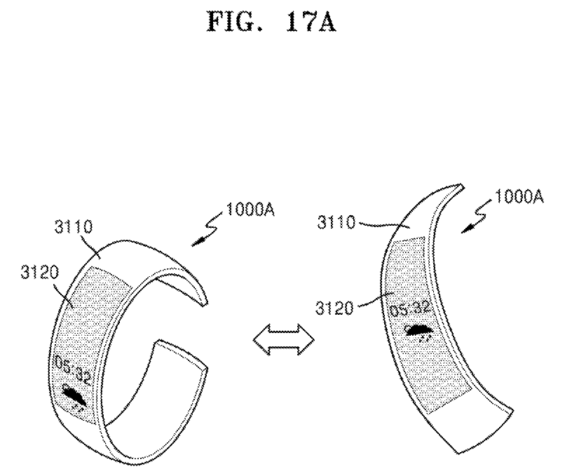

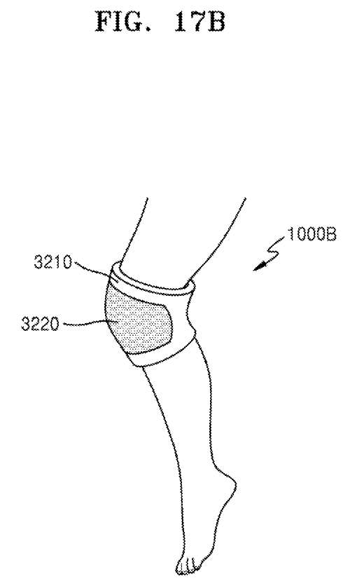

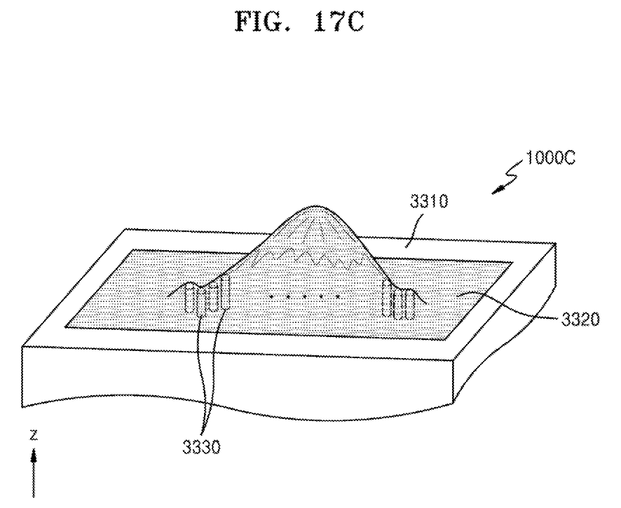

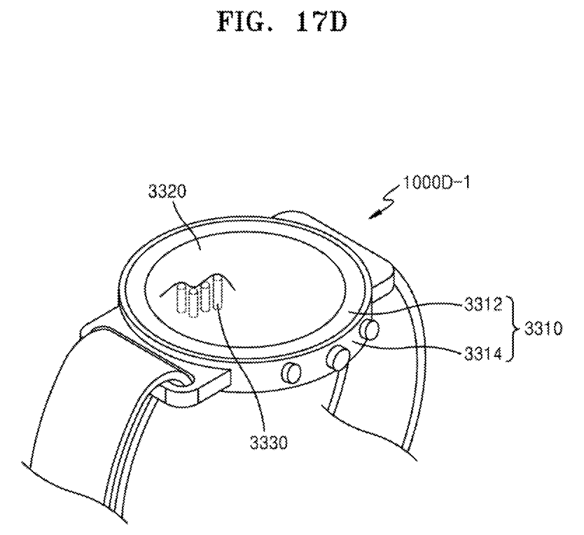

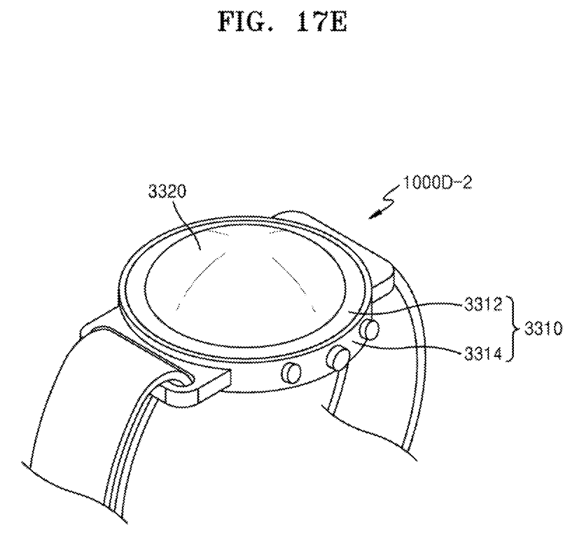

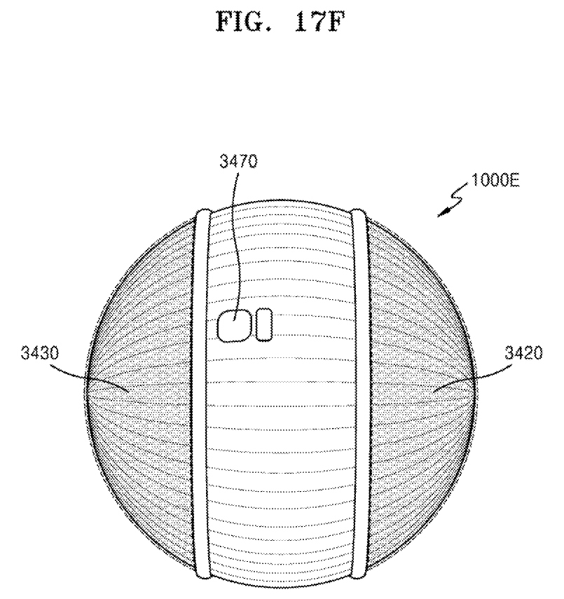

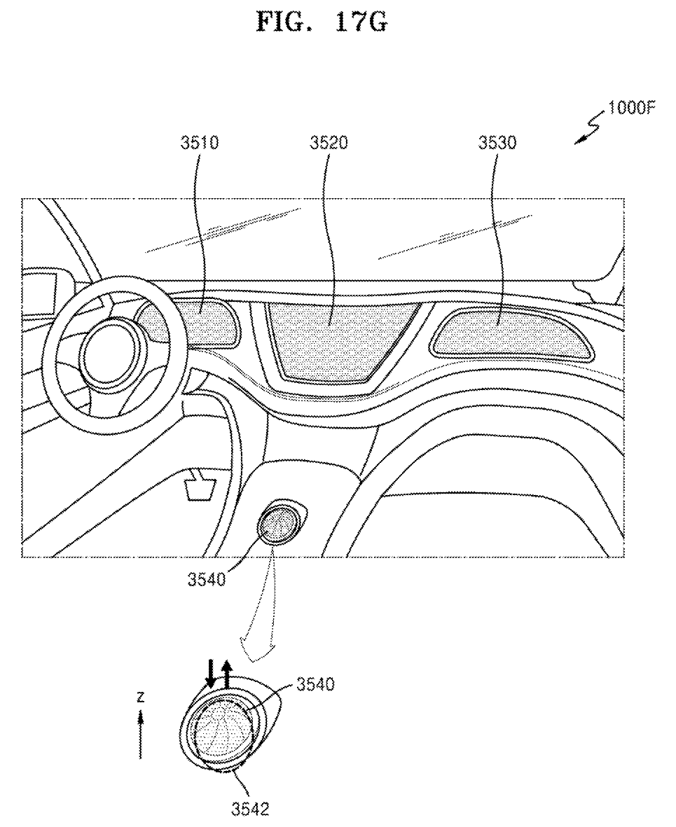

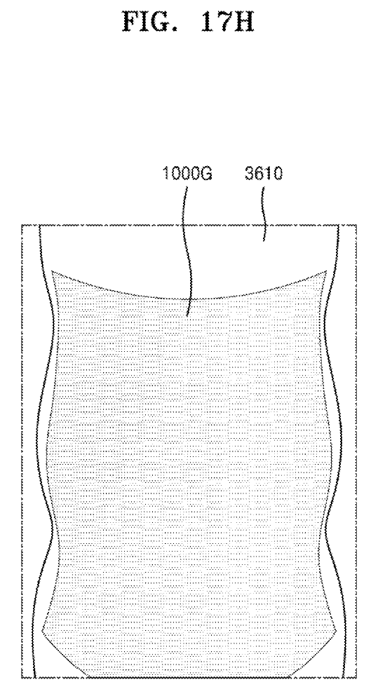

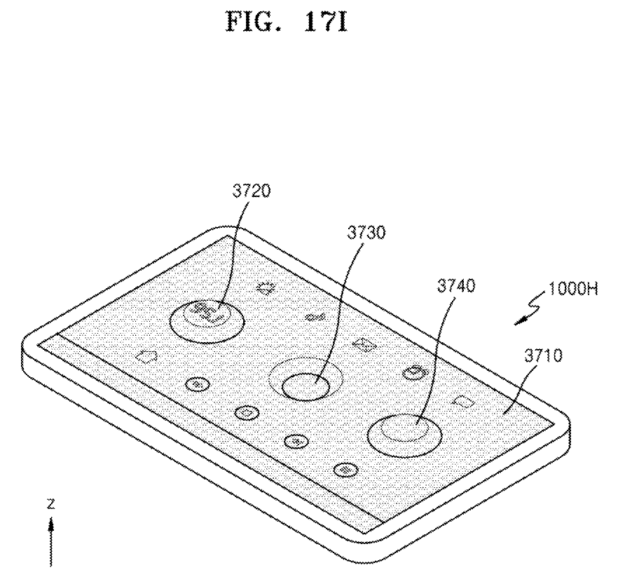

FIGS. 17A to 17I are schematic perspective views of an electronic device including a display panel according to one or more embodiments of the present disclosure.

Referring to FIG. 17A, the display panel according to one or more embodiments may be utilized in a wearable electronic device 1000A that may be worn on a portion of a user's body. The wearable electronic device 1000A may include a body portion 3110 and a display portion 3120 provided to the body portion 3110. The display panel according to embodiments may be used as the display portion 3120 of the wearable electronic device 1000A. As shown in FIG. 17A, the wearable electronic device 1000A may be transformed. In one or more embodiments, the wearable electronic device 1000A may be used as a smartwatch or a smartphone according to a user’s selection.

FIG. 17B shows a medical electronic device 1000B. In one or more embodiments, the medical electronic device 1000B may include a body portion 3210 and a light-emitting portion 3220. The display panel according to embodiments may be used as the light-emitting portion 3220 of the medical electronic device 1000B. The light-emitting portion 3220 may emit light (e.g., infrared rays, visible rays, and/or the like) in a corresponding wavelength band (e.g., preset wavelength band) to a patient’s body. In one or more embodiments, the body portion 3210 may include a stretchable fiber material, and may have a structure that may be worn on the body of a user.

FIG. 17C shows an educational electronic device 1000C. In one or more embodiments, the educational electronic device may include a display portion 3320 provided inside a body portion 3310. The display portion 3320 may be used as the display panel according to the embodiments of the present disclosure. An image, such as a sea with crashing waves, a snow-covered mountain, or a volcano with flowing lava can be provided through the display portion 3320, and in this case, the display portion 3320 may be stretched in a height direction (e.g., z direction) to reflect the height of the wave, mountain, or volcano. In one or more embodiments, a portion of the display portion 3320 may be configured to sequentially change its height in a direction in which the lava flows, thereby showing the movement of the lava three dimensionally. The educational electronic device 1000C may include a plurality of pins 3330 (or a stroke portion) located on the rear surface of the display portion 3320 such that the display portion 3320 is stretched in the height direction. The pins 3330 may be implemented to move in the third direction (e.g., z direction or -z direction) such that an image expressed on the display portion 3320 has a height three dimensionally. Although FIG. 17C describes the educational electronic device 1000C, the purpose thereof is not limited thereto as far as the educational electronic device provides corresponding image information (e.g., preset image information).

FIGS. 17D and 17E show the display panel is used in wearable electronic devices 1000D-1 and 1000D-2, such as a smartwatch.

In one or more embodiments, as shown in FIG. 17D, because the display panel corresponding to the display portion 3320 of the electronic device 1000D-1 is stretchable three-dimensionally, the display panel may provide, to a user, various haptic information in addition to visual information through images. In one or more embodiments, the electronic device 1000D-1 may provide haptic information, such as Braille display for the visually impaired or tactile stimulation linked to an image, by using a plurality of pins 3330 (or stroke portions) located below the display portion 3320. Because the display panel forming the display portion 3320 is stretchable three-dimensionally, the display panel may provide the haptic information to a user. The electronic device 1000D-1 may include the body portion 3310, wherein the body portion 3310 includes a housing 3314 in which the display panel forming the display portion 3320 and the pins 3330 (or stroke portions) are accommodated, and a frame 3312 that may be coupled to the housing 3314 with the display panel therebetween. In one or more embodiments, the frame 3312 may be integrally formed with the housing 3314.

The electronic device 1000D-2 of FIG. 17E may include the body portion 3310 and the display portion 3320 accommodated in the body portion 3310 and providing visual information as in FIG. 15D. In one or more embodiments, because the display panel corresponding to the display portion 3320 is stretchable three-dimensionally, the display panel may include the display portion 3320 of a dome shape. In one or more embodiments, the display panel may be assembled to the body frame of a dome shape during the process of manufacturing the electronic device 1000D-2, and in this case, because the display panel is stretchable three-dimensionally, the display panel may be assembled while being stretched along the shape of the hemispherical body frame.

FIG. 17F shows an electronic device 1000E according to one or more embodiments of the present disclosure includes a robot. The robot may recognize a movement or object using a camera module 3470 and display corresponding images (e.g., preset images) to a user through display portions 3420 and 3430.

In one or more embodiments, because the display panels according to one or more embodiments may be stretched in various directions as described above, the display panels may be assembled to the body frame having a hemispherical shape, and thus, the robot may include the display portions 3420 and 3430 of a hemispherical shape.

FIG. 17G shows a vehicle display device 1000F as an electronic device according to one or more embodiments of the present disclosure. The vehicle display device 1000F may include a cluster 3510, a center information display (CID) 3520, and/or a co-driver display 3530. Because the display panel according to one or more embodiments may be stretched in various directions, the display panel may be used in the cluster 3510, the CID 3520, and/or the co-driver display 3530 without being restricted by the shape of an internal frame of the vehicle.

Although it is shown in FIG. 17G that the cluster 3510, the CID 3520, and/or the co-driver display 3530 are separated from each other, the present disclosure is not limited thereto. In one or more other embodiments, two or more selected from the cluster 3510, the CID 3520, and the co-driver display 3530 may be integrally connected.

In one or more embodiments, the vehicle display device 1000F may include a button 3540 that may express corresponding images (e.g., preset images). Referring to an enlarged view of FIG. 17G, the button 3540 of a hemispherical shape may include an object 3542 and a display panel located on the object 3542, wherein the object 3542 provides the feel of a button while moving in the z direction or -z-direction. In one or more embodiments, in the case where the object 3542 has a three- dimensionally round surface, the display panel may also have a three-dimensionally round surface.

FIG. 17H shows an electronic device according to one or more embodiments of the present disclosure is an electronic device 1000G for advertising or display. In one or more embodiments, the electronic device 1000G for advertising or display may be installed on a fixed structure 3610, such as a wall or pole. In the case where the structure 3610 includes an uneven surface as shown in FIG. 17G, the electronic device 1000G for advertising or display may be also located along the uneven surface of the structure 3610. In one or more embodiments, the electronic device 1000G for advertising or display may be installed on the structure 3610 using a heat shrink film.

FIG. 17I shows an electronic device 1000H according to one or more embodiments of the present disclosure is a controller. The controller may include an image-type button. As an example, the controller may include first to third button regions 3720, 3730, and 3740 in which a portion of the display portion 3710 protrudes in the z direction or protrudes in the -z direction (or is recessed in the z direction). In one or more embodiments, the first and third button regions 3720 and 3740 may protrude in the z direction, and the second button region 3730 may protrude in the -z direction (or may be recessed in the z direction).

While the disclosure has been described with reference to one or more embodiments shown in the drawings, it will be understood by those of ordinary knowledge in the art that these are just examples and various changes and equivalent other embodiments may be made therefrom. Accordingly, the true technical scope of the present disclosure should be defined by the spirit of the appended claims, with functional equivalents thereof to be included therein.

### Description of Some of the Reference Characters

1: electronic device 10: display panel

DA: display area NDA: non-display area

PC: pixel circuit LED: light-emitting diode

11: first region 12: second region

WL: connection wiring WLm: main connection wiring

WLs: auxiliary connection wiring

WLs1, WLs2, WLs3, WLs4: first to fourth auxiliary connection wirings

What is claimed is:

1. A display panel comprising:
a base layer comprising first regions, and a second region surrounding the first regions;
a pixel circuit layer above the base layer, and comprising pixel circuits and insulating layers in the first regions;
light-emitting diodes above the pixel circuit layer, and respectively electrically connected to the pixel circuits; and
a connection wiring electrically connecting adjacent ones of the pixel circuits, and comprising a stacked structure of a main connection wiring comprising a two-dimensional nanostructure, and an auxiliary connection wiring comprising a one-dimensional nanostructure and a zero-dimensional nanostructure.

2. The display panel of claim 1, wherein the two-dimensional nanostructure of the main connection wiring comprises at least one of a nanoflake, a nano sheet, or a nanoplate.

3. The display panel of claim 1, wherein the one-dimensional nanostructure of the auxiliary connection wiring comprises at least one of a nanowire, a nanofiber, a nanotube, a nanorod, or a nanobelt.

4. The display panel of claim 1, wherein the zero-dimensional nanostructure of the auxiliary connection wiring comprises a nanoparticle.

5. The display panel of claim 1, wherein the two-dimensional nanostructure, the one-dimensional nanostructure, and the zero-dimensional nanostructure comprise a metal-based nanostructure.

6. The display panel of claim 5, wherein the two-dimensional nanostructure comprises an Ag nanoflake,
wherein the one-dimensional nanostructure comprises an Ag nanowire, and
wherein the zero-dimensional nanostructure comprises an Ag nanoparticle.

7. The display panel of claim 1, wherein the auxiliary connection wiring comprises a mixture of the one-dimensional nanostructure and the zero-dimensional nanostructure.

8. The display panel of claim 1, wherein the auxiliary connection wiring comprises:
a first auxiliary connection wiring comprising the one-dimensional nanostructure above the main connection wiring; and
a second auxiliary connection wiring comprising the zero-dimensional nanostructure above the first auxiliary connection wiring.

9. The display panel of claim 1, further comprising a conductive line in direct contact with the auxiliary connection wiring, and connecting the pixel circuits and the connection wiring to each other.

10. The display panel of claim 1, wherein the auxiliary connection wiring is above the main connection wiring,
wherein the connection wiring further comprises a third auxiliary connection wiring under the main connection wiring, comprising a different material from the main connection wiring and the auxiliary connection wiring, and comprising a carbon nanostructure.

11. The display panel of claim 1, wherein the auxiliary connection wiring is above the main connection wiring,
wherein the connection wiring further comprises:
a third auxiliary connection wiring comprising a two-dimensional carbon nanostructure under the main connection wiring; and
a fourth auxiliary connection wiring comprising a one-dimensional carbon nanostructure under the third auxiliary connection wiring, and
wherein the third auxiliary connection wiring and the fourth auxiliary connection wiring respectively comprise different materials from the main connection wiring and the auxiliary connection wiring.

12. The display panel of claim 1, wherein an interface where the main connection wiring and the auxiliary connection wiring are in contact is surface-processed using a polymer process or a plasma process.

13. The display panel of claim 1, wherein the main connection wiring and the auxiliary connection wiring further comprise a same elastic polymer material, and
wherein the base layer comprises a same material as an elastic polymer material of the connection wiring.

14. A display panel comprising:
a base layer comprising first regions, and a second region surrounding the first regions;
a first pixel circuit layer above one of the first regions of the base layer, and comprising a transistor and insulating layers;
a second pixel circuit layer above another of the first regions of the base layer, and comprising a transistor and insulating layers;
a first light-emitting diode above the first pixel circuit layer, and electrically connected to the transistor of the first pixel circuit layer;
a second light-emitting diode above the second pixel circuit layer, and electrically connected to the transistor of the second pixel circuit layer; and
a connection wiring electrically connecting the transistor of the first pixel circuit layer to the transistor of the second pixel circuit layer, and comprising a main connection wiring and an auxiliary connection wiring comprising respective nanostructures of different dimensions.

15. The display panel of claim 14, wherein the main connection wiring comprises a two-dimensional nanostructure comprising at least one of a nanoflake, a nano sheet, or a nanoplate.

16. The display panel of claim 14, wherein the auxiliary connection wiring comprises at least one of a one-dimensional nanostructure comprising at least one of a nanowire, a nanofiber, a nanotube, a nanorod, or a nanobelt, or a zero-dimensional nanostructure comprising a nanoparticle.

17. The display panel of claim 14, wherein the main connection wiring and the auxiliary connection wiring comprise a same metal, and comprise different nanostructure materials from each other.

18. An electronic device comprising a display panel, the display panel comprising:
a base layer comprising first regions, and a second region surrounding the first regions;
a pixel circuit layer above the base layer, and comprising pixel circuits and insulating layers in the first regions;
light-emitting diodes above the pixel circuit layer, and respectively electrically connected to the pixel circuits; and
a connection wiring electrically connecting adjacent ones of the pixel circuits, and comprising a stacked structure of a main connection wiring comprising a two-dimensional nanostructure, and an auxiliary connection wiring comprising a one-dimensional nanostructure and a zero-dimensional nanostructure.

19. The electronic device of claim 18, wherein the two-dimensional nanostructure comprises at least one of a nanoflake, a nano sheet, or a nanoplate,
wherein the one-dimensional nanostructure comprises at least one of a nanowire, a nanofiber, a nanotube, a nanorod, or a nanobelt, and
wherein the zero-dimensional nanostructure comprises a nanoparticle.

20. The electronic device of claim 18, wherein the two-dimensional nanostructure of the main connection wiring and the one-dimensional nanostructure or the zero-dimensional nanostructure of the auxiliary connection wiring comprise a same metal.
